(19) United States
(12) Patent Application Publication
(10) Pub. No.: US 2021/0342997 A1
(43) Pub. Date: Nov. 4, 2021

(54) Computer Vision Systems and Methods for Vehicle Damage Detection with Reinforcement Learning

(71) Applicant: Insurance Services Office, Inc., Jersey City, NJ (US)

(72) Inventors: Siddarth Malreddy, Sunnyvale, CA (US); Sashank Jujjavarapu, Sunnyvale, CA (US); Abhinav Gupta, Pittsburgh, PA (US); Maneesh Kumar Singh, Princeton, NJ (US); Yash Patel, Prague (CZ); Shengze Wang, Champaign, IL (US)

(73) Assignee: Insurance Services Office, Inc., Jersey City, NJ (US)

(21) Appl. No.: 17/123,589

(22) Filed: Dec. 16, 2020

Related U.S. Application Data
(60) Provisional application No. 62/948,489, filed on Dec. 16, 2019.
(60) Provisional application No. 62/948,497, filed on Dec. 16, 2019.

(51) Int. Cl. G06T 7/00; G06T 17/20; G06T 7/50; G06T 7/70; G06T 7/11; G06K 9/62; G06F 30/27; G06F 30/15; G06N 3/08; G07C 5/00

(52) U.S. Cl. CPC G06T 7/0002; G06T 17/20; G06T 7/50; G06T 7/70; G06T 7/11; G06K 9/6267; G06K 2209/23; G06F 30/27; G06F 30/15; G06N 3/08; G07C 5/006; G06T 2207/20081; G06T 2207/20084; G06K 9/6256

(57) ABSTRACT

Computer vision systems and methods for vehicle damage detection are provided. An embodiment of the system generates a dataset and trains a neural network with a plurality of images of the dataset to learn to detect an attribute of a vehicle present in an image of the dataset and to classify at least one feature of the detected attribute. The system can detect the attribute of the vehicle and classify the at least one feature of the detected attribute by the trained neural network. In addition, an embodiment of the system utilizes a neural network to reconstruct a vehicle from one or more digital images.

### RELATED APPLICATIONS

This application claims priority to U.S. Provisional Patent Application Ser. No. 62/948,489 filed on Dec. 16, 2019 and U.S. Provisional Patent Application Ser. No. 62/948,497 filed on Dec. 16, 2019, each of which is hereby expressly incorporated by reference.

### BACKGROUND

### Technical Field

The present disclosure relates generally to the field of computer vision technology. More specifically, the present disclosure relates to computer vision systems and methods for vehicle damage detection and classification with reinforcement learning.

### Related Art

Vehicle damage detection refers to detecting damage of a detected vehicle in an image. In the vehicle damage detection field, increasingly sophisticated software-based systems are being developed for automatically detecting damage of a detected vehicle present in an image. Such systems have wide applicability, including but not limited to, insurance (e.g., title insurance and claims processing), re-insurance, banking (e.g., underwriting auto loans), and the used vehicle market (e.g., vehicle appraisal).

Conventional vehicle damage detection systems and methods suffer from several challenges that can adversely impact the accuracy of such systems and methods including, but not limited to, lighting, reflections, vehicle curvature, a variety of exterior paint colors and finishes, a lack of image databases, and criteria for false negatives and false positives. Additionally, conventional vehicle damage detection systems and methods are limited to merely detecting vehicle damage (i.e., whether a vehicle is damaged or not) and cannot determine a location of the detected vehicle damage nor an extent of the detected vehicle damage.

There is currently significant interest in developing systems that automatically detect vehicle damage, determine a location of the detected vehicle damage, and determine an extent of the detected and localized vehicle damage of a vehicle present in an image requiring no (or, minimal) user involvement, and with a high degree of accuracy. For example, it would be highly beneficial to develop systems that can automatically generate vehicle insurance claims based on images submitted by a user. Accordingly, the system of the present disclosure addresses these and other needs.

### SUMMARY

The present disclosure relates to computer vision systems and methods for vehicle damage detection and classification with reinforcement learning. An embodiment of the system generates a dataset, which can include digital images of actual vehicles or simulated (e.g., computer-generated) vehicles, and trains a neural network with a plurality of images of the dataset to learn to detect damage to a vehicle present in an image of the dataset and to classify a location of the detected damage and a severity of the detected damage utilizing segmentation processing. The system can detect the damage to the vehicle and classify the location of the detected damage and the severity of the detected damage by the trained neural network where the location of the detected damage is at least one of a front, a rear or a side of the vehicle and the severity of the detected damage is based on predetermined damage sub-classes. In addition, an embodiment of the system utilizes a neural network to reconstruct a vehicle from one or more digital images.

### BRIEF DESCRIPTION OF THE DRAWINGS

The foregoing features of the invention will be apparent from the following Detailed Description of the Invention, taken in connection with the accompanying drawings, in which:

FIG. 1 is a flowchart illustrating an overview of vehicle damage detection processing performed by a conventional vehicle damage detection system;

FIG. 2 is a diagram illustrating the overall system of the present disclosure;

FIG. 3 is a flowchart illustrating the overall processing steps carried out by the system of the present disclosure;

FIGS. 4A-C are real dataset images illustrating types of vehicle damage according to an embodiment of the present disclosure;

FIG. 5 is a flowchart illustrating vehicle damage classification processing steps carried out by the system of the present disclosure;

FIG. 6A is a diagram illustrating a convolutional neural network (CNN) for performing vehicle damage classification processing on real vehicle data according to an embodiment of the system of the present disclosure;

FIG. 6B is a chart illustrating results of the vehicle damage classification processing performed by the CNN of FIG. 6A;

FIG. 7 is a flowchart illustrating overall processing steps for generating a simulated dataset according to an embodiment of the system of the present disclosure;

FIGS. 8A-B are screenshot images illustrating a simulated vehicle door component according to an embodiment of the present disclosure;

FIG. 9 is a screenshot image illustrating a damage setup of a simulated vehicle;

FIGS. 10A-B are screenshot images respectively illustrating a simulated vehicle door component with and without damage;

FIGS. 11A-13B are simulated dataset images generated by the dataset generation module 14 of FIG. 2 according to an embodiment of the present disclosure;

FIG. 14 is a compilation of simulated images illustrating vehicle damage saliency visualization training data;

FIG. 15 is a compilation of simulated images illustrating vehicle damage saliency visualization testing data;

FIGS. 16A-C are diagrams illustrating different neural network models capable of performing segmentation processing on simulated vehicle data according to embodiments of the system of the present disclosure;

FIGS. 17A-B are images illustrating segmentation processing results for vehicle damage training data based on simulated vehicle damage data inputs according to an embodiment of the system of the present disclosure;

FIGS. 18A-B are images illustrating segmentation processing results for vehicle damage test data based on simulated vehicle damage data inputs according to an embodiment of the system of the present disclosure;

FIGS. 19A-D are images illustrating a simulated vehicle generated by the dataset generation module 14 of FIG. 2 according to an embodiment of the system of the present disclosure;

FIGS. 20A-C are images illustrating generated surface normal and depth maps of a simulated vehicle;

FIGS. 21A-E are images illustrating a generated simulated vehicle and simulated damage data according to an embodiment of the system of the present disclosure;

FIG. 22 is a flowchart illustrating vehicle damage detection processing performed by an embodiment of the system of the present disclosure;

FIGS. 23A-B are sets of images illustrating segmentation training set data and testing set data;

FIG. 24A is a diagram illustrating a U-NET-CNN for performing vehicle component segmentation processing according to an embodiment of the system of the present disclosure;

FIG. 24B is a chart illustrating results of the vehicle component segmentation processing performed by the U-Net-CNN of FIG. 24A;

FIGS. 25A-C are images illustrating vehicle damage classifications;

FIG. 26A is a diagram illustrating a VGG-CNN for performing vehicle damage classification processing according to an embodiment of the system of the present disclosure;

FIG. 26B is a chart illustrating results of the vehicle damage classification processing performed by the VGG-CNN of FIG. 26A;

FIG. 27A is a diagram illustrating processing steps carried out by an embodiment of the system of the present disclosure for reconstructing a vehicle from one or more digital images;

FIG. 27B illustrates depth maps generated by the system of FIG. 27A;

FIGS. 28A-G are images illustrating processing results of the system of FIG. 27A;

FIG. 28H is a graph illustrating training loss corresponding to FIGS. 28F-G;

FIGS. 29 and 30 are diagrams illustrating a 3D recurrent reconstruction neural network (3D-R2N2);

FIGS. 31A-D are diagrams of voxel reconstructions generated by a 3D-R2N2 from one or more input images;

FIG. 32 is a diagram illustrating a set of illustrations of voxel reconstructions generated by a 3D-R2N2 from a single real image;

FIG. 33 is a diagram illustrating an Octree Generation Network (OctNet) for generating 3D objection reconstructions according to an embodiment of the system of present disclosure;

FIGS. 34A-B are diagrams illustrating processing performed by the OctNet of FIG. 33;

FIGS. 35A-B are charts illustrating processing performance benefits of the OctNet of FIG. 33;

FIGS. 36A-C are diagrams illustrating voxel reconstructions generated by the OctNet of FIG. 33 from a single input image; and

FIG. 37 is a diagram showing hardware and software components of a computer system on which the system of the present disclosure can be implemented.

### DETAILED DESCRIPTION

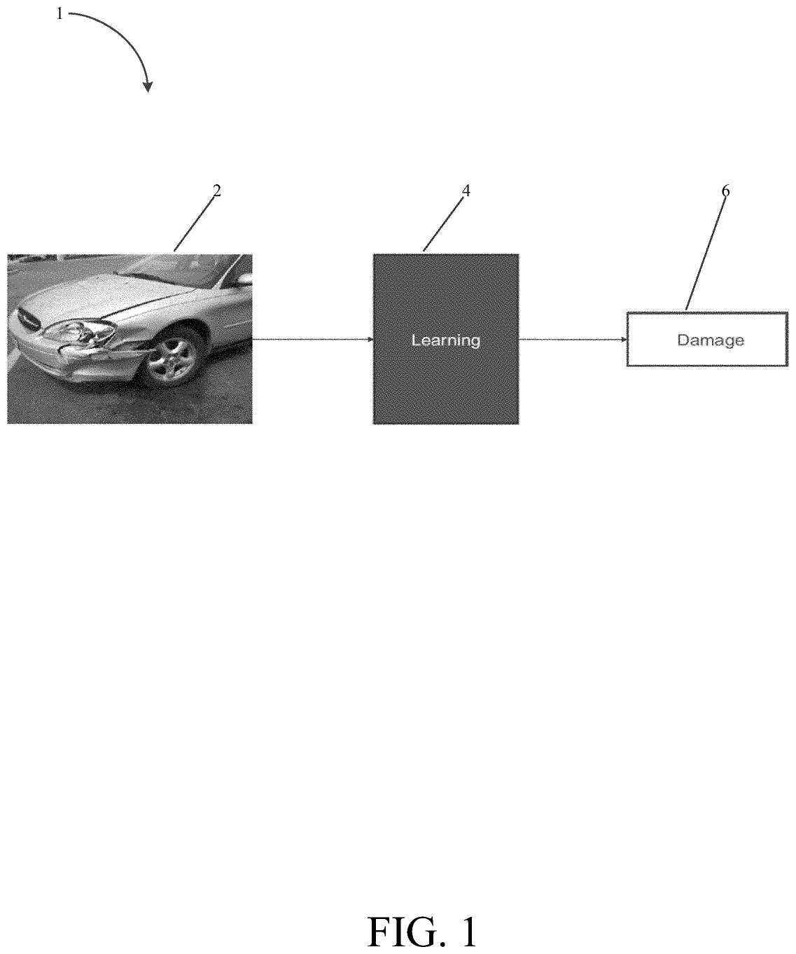

The present disclosure relates to computer vision systems and methods for vehicle damage detection with reinforcement learning and reconstruction, as described in detail below in connection with FIGS. 1-37.

By way of background and before describing the system and method of the present disclosure in detail, the structure, properties, and functions of conventional vehicle damage detection systems and methods with reinforcement learning will be discussed first. FIG. 1 is a flowchart 1 illustrating an overview of vehicle damage detection processing performed by a conventional vehicle damage detection system. Beginning, in step 2, the system receives an image illustrating vehicle damage. Then, in step 4, the system processes the image according to a set of predetermined parameters. Lastly, in step 6, the system identifies vehicle damage present in the image based on the set of predetermined parameters. It is noted that damage can include, but it not limited to, superficial damage such as a scratch or paint chip and deformation damage such as a dent.

Conventional vehicle damage detection systems and methods suffer from several challenges that can adversely impact the accuracy of such systems and methods including, but not limited to, lighting, reflections, vehicle curvature, a variety of exterior paint colors and finishes, a lack of image databases, and criteria for false negatives and false positives. Some challenges can be more difficult to overcome than others. For example, online repositories suffer from a lack of image databases having vehicle damage datasets and/or vehicle damage labeled datasets. A lack of image databases adversely impacts the ability of a vehicle damage detection system to train and learn to improve an accuracy of the vehicle damage detection system. Other vehicle damage dataset sources such as video games are difficult to rely upon because ground truth data is generally inaccessible. This can be problematic because ground truth data can clarify discrepancies within a dataset.

Therefore, in accordance with the systems and methods of the present disclosure, an approach to improving the accuracy of such systems includes building image databases having real datasets by collecting real images of vehicle damage and building image databases having simulated datasets by utilizing simulation software to generate simulated images of vehicle damage. Real datasets include real images whereas simulated datasets include images generated via simulation software including, but not limited to, the Unreal Engine, Blender and Unity software packages. Deep learning and reinforcement learning performed on each of real datasets and simulated datasets provides for improved vehicle damage detection and classification.

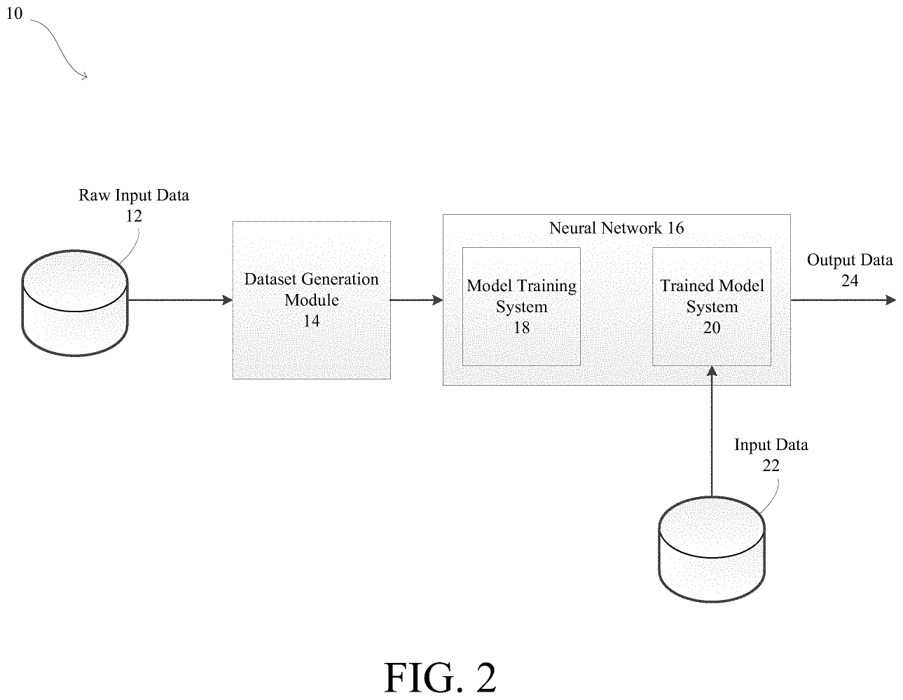

FIG. 2 is a diagram illustrating the system 10 of the present disclosure. The system 10 includes a dataset generation module 14 which receives raw input data 12, and a neural network 16 which can receive input data 22 and generate output data 24. The neural network 16 comprises a model training system 18 and a trained model system 20. The neural network 16 can be any type of neural network or machine learning system, or combination thereof. For example, the neural network 16 can be a deep neural network capable of, for example, image classification and saliency visualization, a convolutional neural network (“CNN”), an artificial neural network (“ANN”), a recurrent neural network (“RNN”), etc. The neural network 16 can use one or more frameworks (e.g., interfaces, libraries, tools, etc.) such as Keras, TensorFlow, Torch, CAFFE, Sonnet, etc. The system 10 of the present disclosure could be executed with programming languages such as Python and Lua. Additionally, hardware capable of performing vehicle damage detection could include, but it not limited to, a central processing unit (CPU) having at least 32 gigabytes (GB) of random access memory (RAM) and a graphics processing unit (e.g., a Nvidia Titan X).

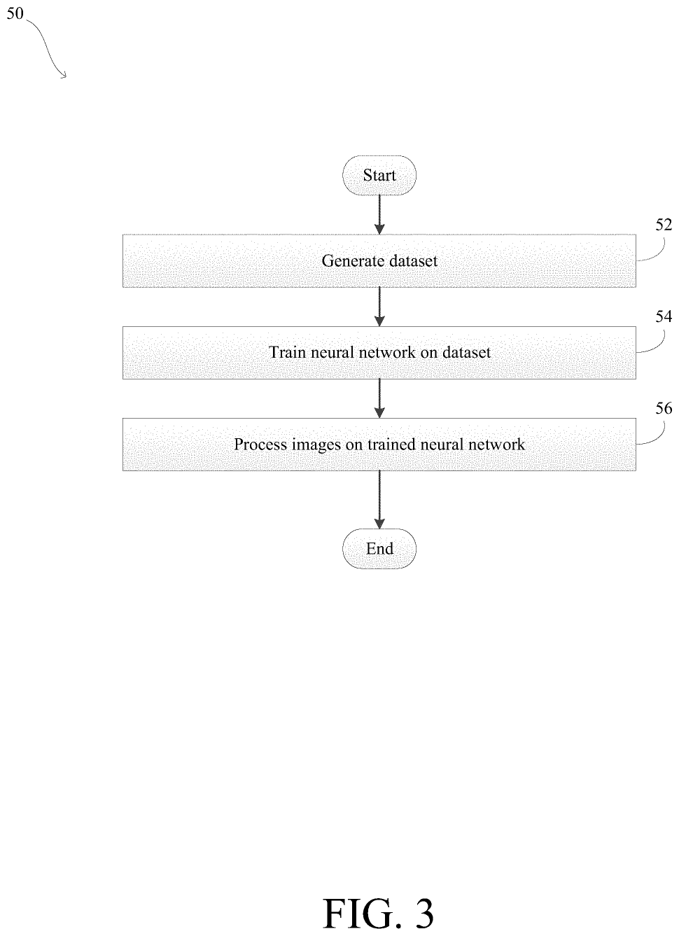

FIG. 3 is a flowchart 50 illustrating the overall processing steps carried out by the system 10 of the present disclosure. Beginning in step 52, the dataset generation module 14 generates at least one dataset. As discussed above, a dataset can include a real dataset or a simulated dataset. For example, the raw input data 12 can include real digital images of vehicles with or without damage and the dataset generation module 14 can process the raw input data 12 to generate a real dataset. In particular, the dataset generation module 14 can generate a real dataset by at least one of combining labeled digital images into a dataset, utilizing an existing dataset (e.g., a Github database), combining different datasets and/or labelling digital images and combining the labeled images into a dataset. Alternatively, the dataset generation module 14 can generate a simulated dataset utilizing simulation software including, but not limited to, the Unreal Engine, Blender and Unity software packages. In particular, the dataset generation module 14 can generate one or more simulated (e.g., computer-generated or rendered) vehicles utilizing simulation software and subsequently utilize a physics engine or programming script to generate damage to the one or more simulated vehicles.

A real dataset and a simulated dataset can each illustrate vehicle damage including, but not limited to, superficial damage such as a scratch or paint chip and deformation damage such as a dent or an extreme deformation. To train the neural network 16, each dataset image can be labeled based on a location of sustained damage and a classification thereof relating to a severity of the damage corresponding to predetermined damage classes. For example, the system 10 can classify a severity of vehicle damage according to a minor damage class, a moderate damage class or a severe damage class. The minor damage class can include damage indicative of a scratch, a scrape, a ding, a small dent, a crack in a headlight, etc. The moderate damage class can include damage indicative of a large dent, a deployed airbag, etc. The severe damage class can include damage indicative of a broken axle, a bent or twisted frame, etc. It should be understood that the system 10 can utilize a variety of damage classes indicative of different types of vehicle damage.

In step 54, the model training system 18 trains the neural network 16 on the dataset. Training the neural network 16 can include an iterative learning process in which input values (e.g., data from the dataset) are sequentially presented to the neural network 16 and weights associated with the input values are sequentially adjusted. During training, the neural network 16 learns to detect vehicles and damage thereof, as well as to resolve issues including, but not limited to, lighting, reflectors, vehicle body curves, different paint colors and finishes, and criteria for false negatives and false positives. In step 56, the trained model system 20 processes images from input data 22 on the trained neural network. The input data 22 can include, but is not limited to, images of an automobile accident, a natural disaster, etc. The trained model system 20 processes the images to determine whether a vehicle is damaged.

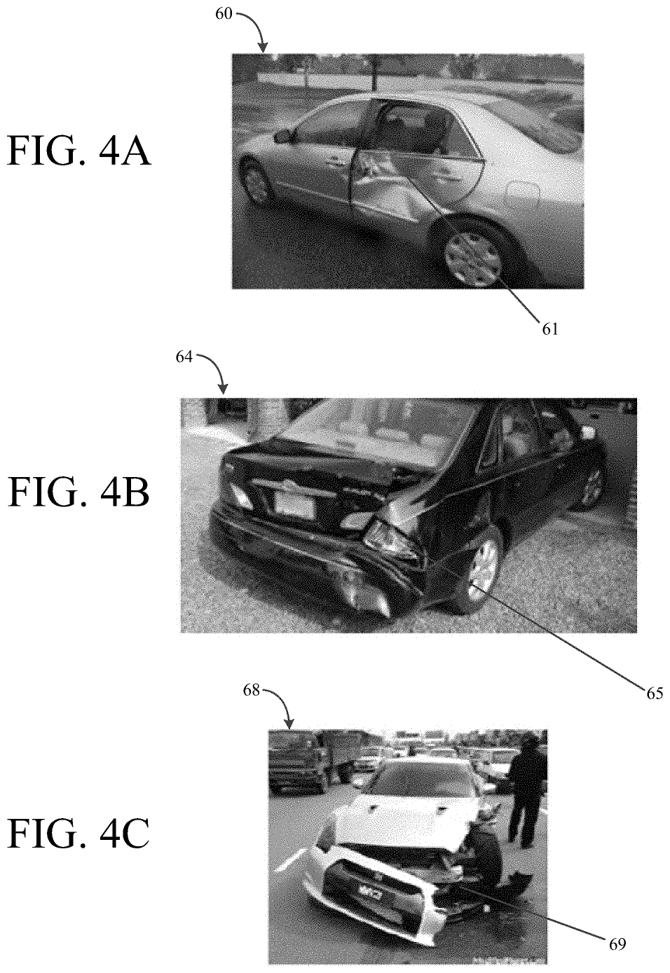

FIGS. 4A-C are real dataset images illustrating different types of vehicle damage according to an embodiment of the present disclosure. Specifically, FIGS. 4A-C are real images sourced from the Car Damage Detective dataset on Github. The Car Damage Detective dataset consists of real images labeled as “damaged” and “undamaged” wherein the real images labeled as “damaged” also include labels indicating a location of the damage and a severity of the damage. FIG. 4A is a real image 60 illustrating a vehicle having left side passenger door damage 61, FIG. 4B is a real image 64 illustrating a vehicle having rear damage 65, and FIG. 4C is a real image 68 illustrating a vehicle having front damage 69. It should be understood that a vehicle can include, but is not limited to, an automobile, a truck, a bus, a motorcycle, an off-road vehicle and any other motorized vehicle. Additionally, it should also be understood that a vehicle can also include an airplane, a ship, a boat, a personal water craft (e.g., a j et ski), a train, etc.

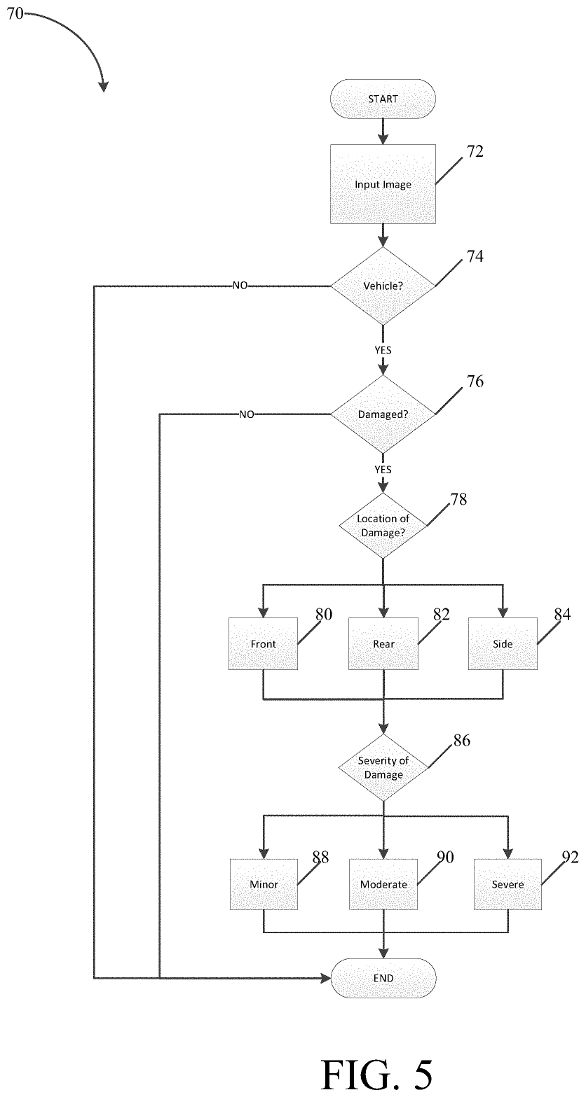

FIG. 5 is a flowchart 70 illustrating vehicle damage classification processing steps carried out by the system 10 of the present disclosure associated with training the neural network 16 (i.e., step 54 of FIG. 3) and processing of images on the trained neural network 16 (i.e., step 56 of FIG. 3). Beginning in step 72, the system 10 receives an input image from a dataset or the input data 22. Then, in step 74, the system 10 determines whether a vehicle is detected in the received image. It is noted that step 74 could be executed based on a predetermined parameter. For example, the system could determine whether a vehicle is detected based on a definition for “vehicle.” If the system does not detect a vehicle in the received image, then the process ends. If the system detects a vehicle in the received image, then the process proceeds to step 76.

In step 76, the system 10 determines whether the detected vehicle in the received image is damaged. If the system 10 determines that the detected vehicle in the received image is not damaged, then the process ends. If the system 10 determines that the detected vehicle in the received image is damaged, then the process proceeds to steps 78. In step 78, the system 10 determines a location of the damage sustained by the detected vehicle in the received image. For example, the system 10 can determine whether the location of the damage includes at least one of a front of the vehicle (e.g., a hood or windshield) in step 80, a rear of the vehicle (e.g., a bumper and trunk) in step 82 and/or a side of the vehicle (e.g., a passenger door) in step 84. In step 86, the system 10 determines a severity classification of the damage sustained by the detected vehicle in the received image. For example, the system 10 can determine whether the sustained damage is minor in step 88, moderate in step 90 or severe in step 92. It should be understood that steps 78 and 86 could be performed sequentially or concurrently and that steps 76, 78 and 86 could be executed by a CNN which is described in more detail below. It should also be understood that the system 10 can identify each part of the detected vehicle, and assess a damage classification relating to the damage severity to each part of the detected vehicle. For example, if an image illustrates a vehicle having sustained severe damage to the windshield and moderate damage to the bumper and trunk, the system 10 can determine that the undamaged classification includes the hood, fenders, and doors, the moderate damage classification includes the bumper and trunk, and the severe classification includes the windshield.

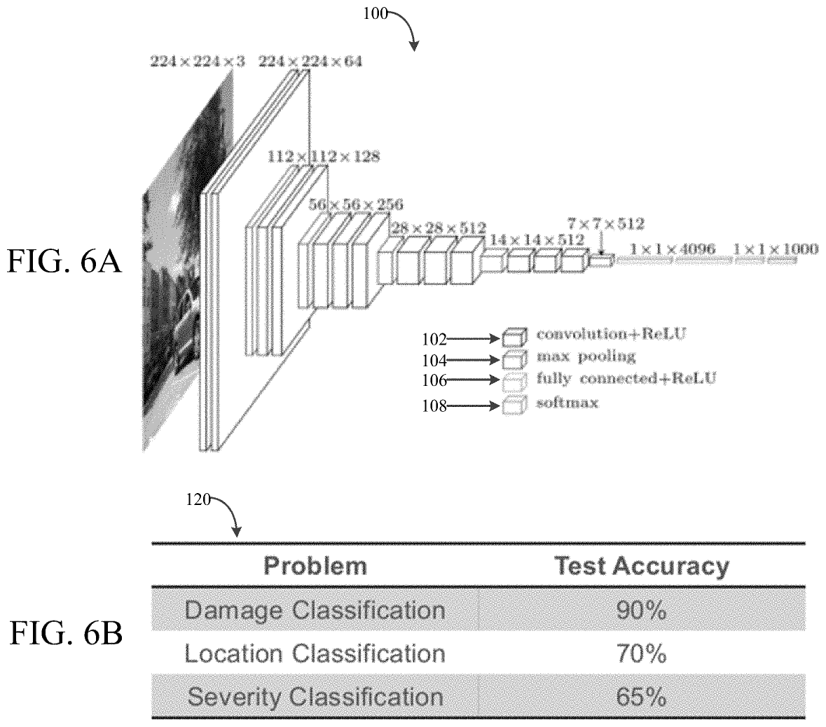

FIG. 6A is a diagram 100 illustrating vehicle damage classification processing performed on real vehicle data by a CNN framework utilized by the system 10 of the present disclosure. A CNN is widely used in machine learning and is an effective tool in various image processing tasks, such as the classification of objects and text analysis. In particular, a CNN can be used as a feature extractor to extract different features and details from an image to identify objects and words present in the image. As shown in FIG. 6A, a Visual Geometry Group (VGG) 16 CNN, is executed over a real vehicle input image to yield features of the image. The VGG-CNN and additional convolution layers progressively decrease a size of the input image at each layer. The layers include one or more convolution layers with a rectified linear unit(s) (“ReLU”) 102, one or more maximum pooling layers 104, one or more fully connected layers with ReLU(s) 106, and one or more softmax layers 108 for further classification. Each layer can apply an operation to a signal from an input node. The result produces an output signal that is fed-forward to a next filter or process in a next layer of the VGG-CNN, or the result can be transformed into an output node. It should be understood that other layers, filters, and/or processes can by utilized by the VGG CNN.

FIG. 6B is a chart 120 illustrating results of the vehicle damage classification processing performed by the VGG-CNN of FIG. 6A. As shown in FIG. 6B, the VGG-CNN yields 90% accuracy in determining damage classification, 70% accuracy in determining location classification, and 65% accuracy in determining damage severity classification.

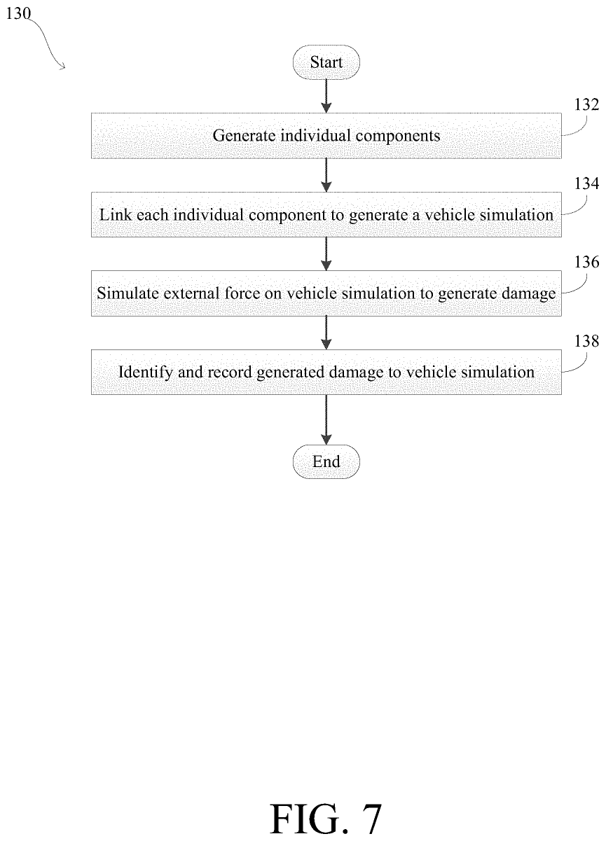

FIG. 7 is a flowchart 130 illustrating overall processing steps for generating a simulated dataset by the dataset generation module 14 of FIG. 2. Specifically, FIG. 7 shows a process for generating a dataset via the Unreal Engine simulation software. In step 132, the system 10 generates individual components where each component is part of a vehicle and can include one or more of a static mesh, a skeletal mesh, a physics asset of the skeletal mesh, and a skeleton (made of bones). In step 134, the system 10 links each vehicle component to generate a vehicle simulation. For example, the system 10 can link each vehicle component by a physics constraint asset (e.g., a hinge). In step 136, the system 10 simulates an external force on the vehicle simulation to generate damage. For example, the system 10 can simulate a projectile (e.g., a brick) contacting a component of the vehicle simulation. In step 138, the system 10 identifies and records the generated damage to the simulated vehicle. The generated damage can include, for example, a color change in the paint, which is controlled by a damage parameter. Specifically, the damage parameter can be increased after impact from an external force. The generated damage can further include a deformation in the static mesh or the skeletal mesh of the vehicle component.

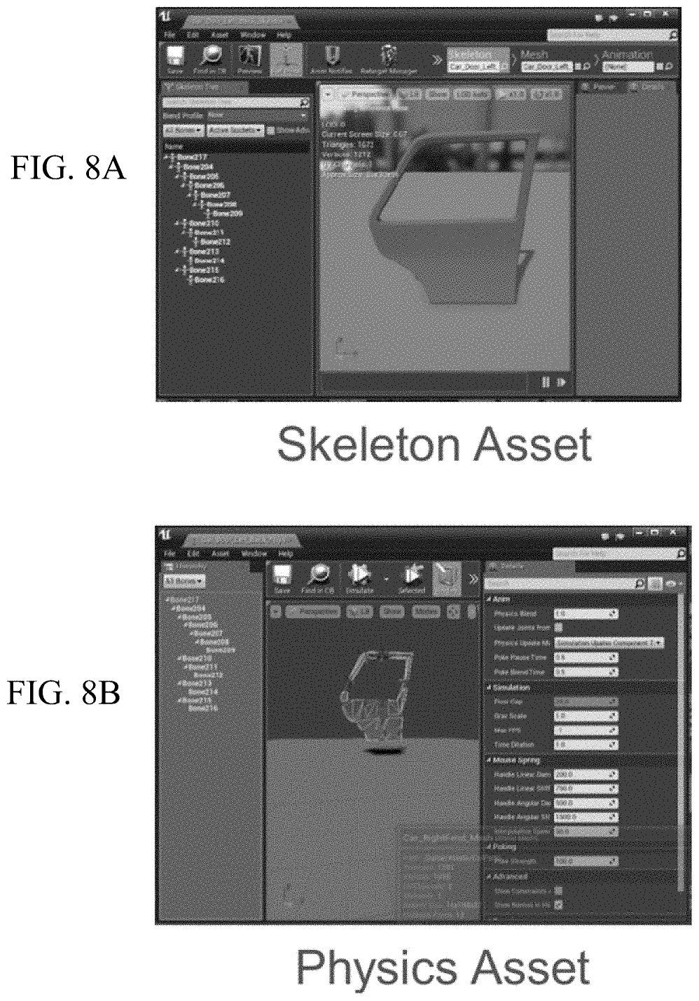

FIGS. 8A-B are screenshot images illustrating a simulated vehicle door component generated by Unreal Engine Torch. Specifically, FIG. 8A is a screenshot illustrating an example skeleton asset of a vehicle door component and FIG. 8B is a screenshot illustrating an example physics asset of a vehicle door component wherein damage sustained by the vehicle door includes superficial damage (e.g., paint damage) and deformation damage (i.e., structural damage). It is noted that Unreal Engine Torch provides for each vehicle component (e.g., a door, a hood, etc.) to include a static mesh, a skeletal mesh, a physics asset of the skeletal mesh and a skeleton asset. It is also noted that each vehicle component is linked by a physics constraint asset (e.g., a hinge) that controls a physical movement of each vehicle component based on the laws of motion.

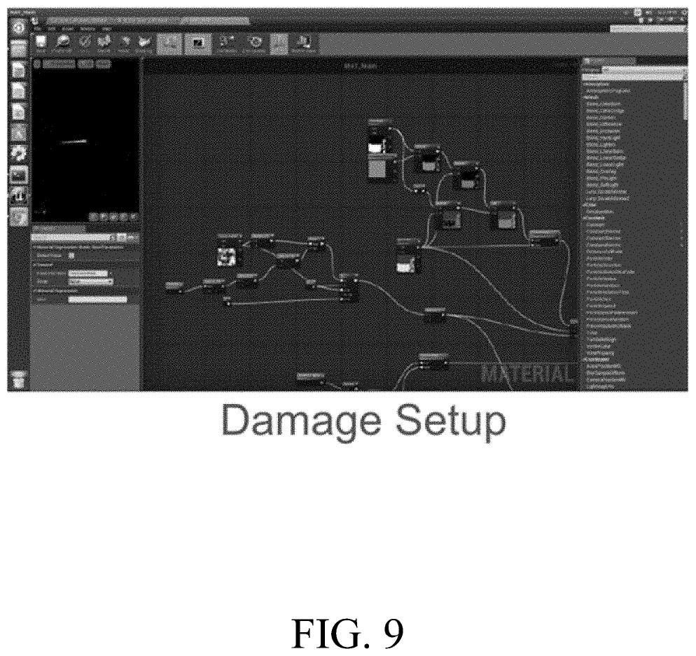

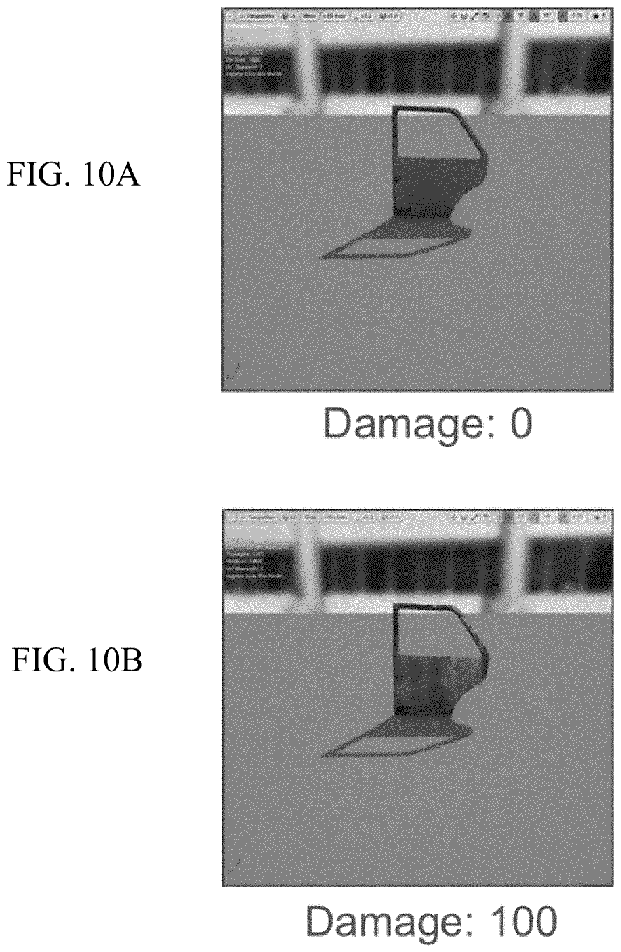

FIG. 9 is a screenshot image illustrating an exemplary damage setup of a simulated vehicle. The damage setup provides for controlling simulated damage sustained by a vehicle or a component thereof. For example, a change in vehicle paint color can be controlled by a damage parameter to reflect contact between a vehicle and a projectile (e.g., a brick). It is noted that the vehicle paint color damage parameter changes the vehicle paint color while the vehicle mesh remains unchanged because mesh deformation is associated with the deformation of bones in the vehicle skeleton. Mesh deformation of the vehicle can be controlled by altering the physics asset such that the vehicle or a component thereof deforms according to the laws of physics. FIGS. 10A-B are screenshot images illustrating the effects of damage sustained by a vehicle door component. Specifically, FIG. 10A illustrates a vehicle door component without damage (e.g., damage level=0) and FIG. 10B illustrates the vehicle door component with deformation damage (e.g., damage level=100).

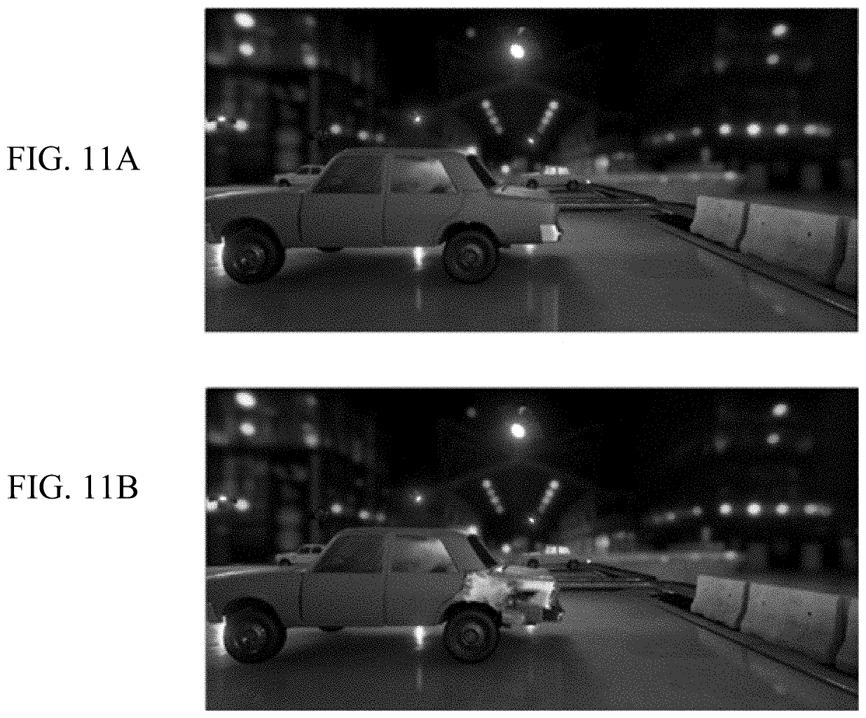

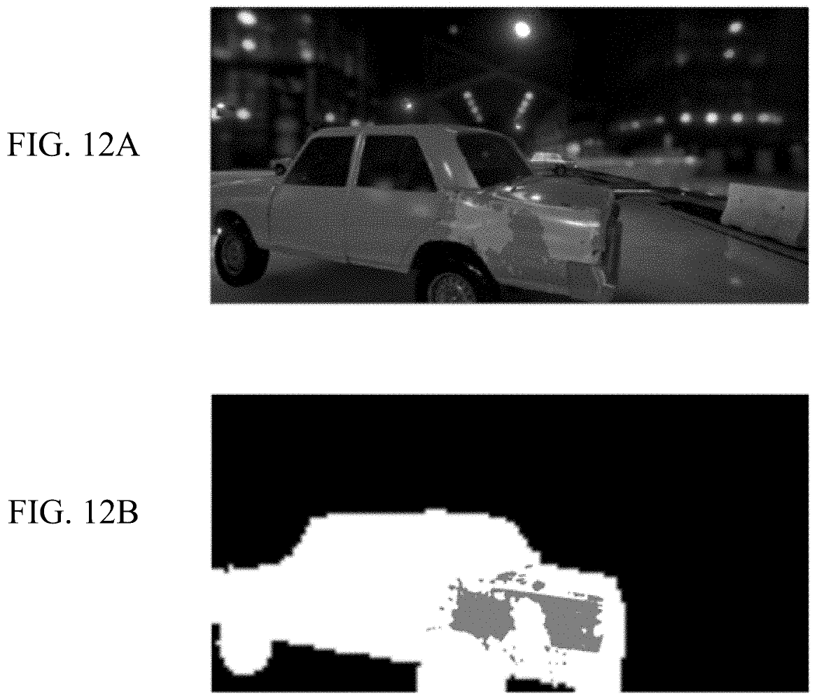

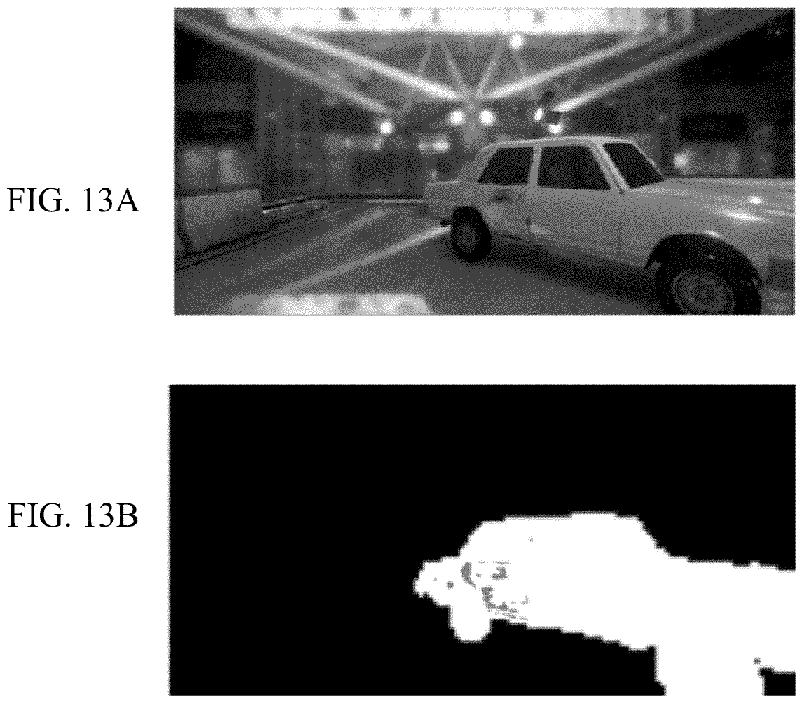

FIGS. 11A-B are simulated dataset images generated by the dataset generation module 14 of FIG. 2 via simulation software. As discussed above, the dataset generation module 14 can utilize simulation software to generate one or more simulated (e.g., computer-generated or rendered) vehicles and a programming script to generate simulated damage to the one or more simulated vehicles. For example, FIGS. 11A-B are reverse engineered screenshot images from an online car game illustrating a simulated vehicle via Unreal Engine simulation software and simulated damage data executed via Lua programming script. FIG. 11A illustrates a ground-truth frame of the simulated vehicle without damage. It should be understood that for each viewpoint of a simulated vehicle, the first frame is a ground truth frame. FIG. 11B illustrates the simulated vehicle with damage to its rear side region. The damage is based on simulating one or more projectiles being thrown at and contacting the vehicle. The damaged and deformed vehicle region is obtained through background subtraction and a vehicle region is obtained through Unreal Engine Torch. FIGS. 12A-B and FIGS. 13A-B are additional examples of simulated dataset images generated by the dataset generation module 14 of FIG. 2 via simulation software. In particular, FIG. 12B shows the damage region of the viewpoint shown in FIG. 12A and FIG. 13B shows the damage region of the viewpoint shown in FIG. 13A.

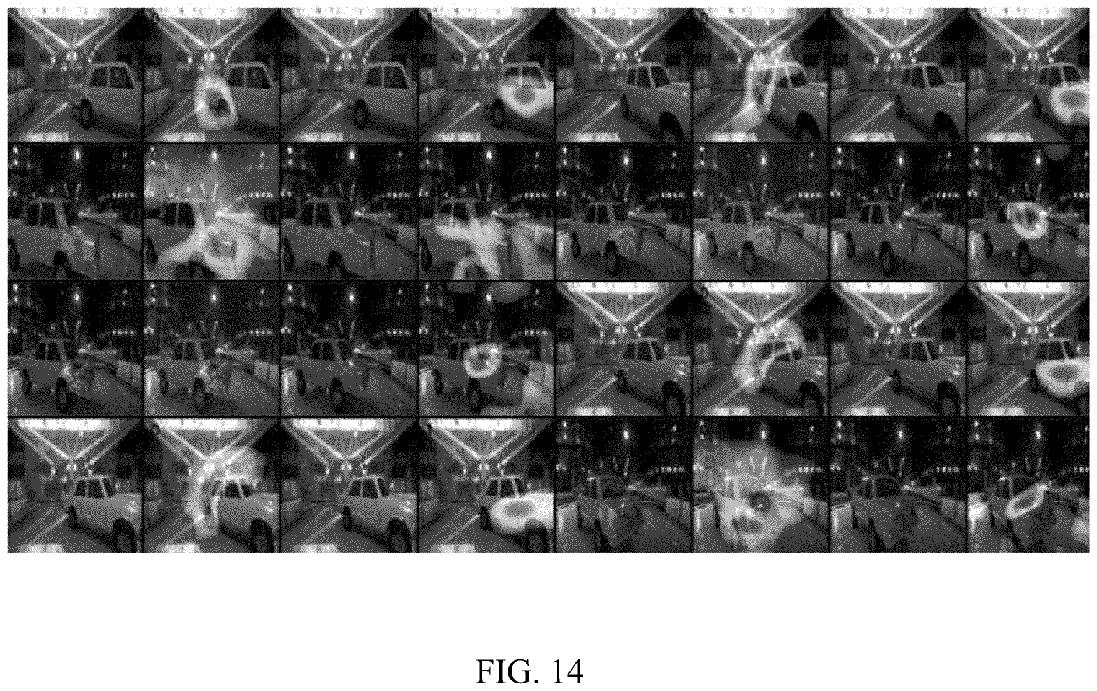

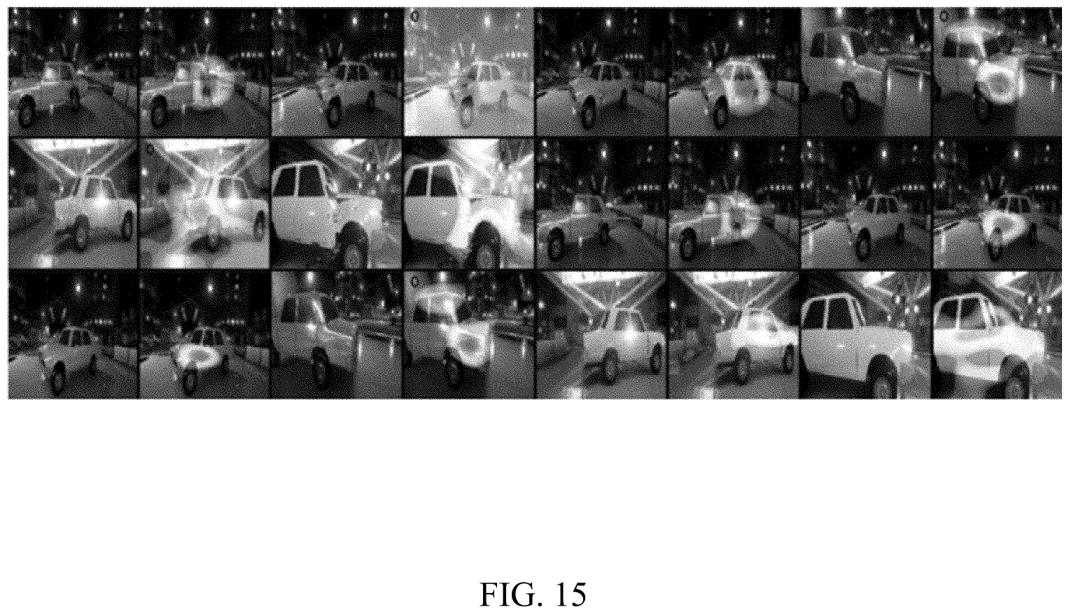

Testing and analysis of the above systems and methods will now be discussed in greater detail. As described above, vehicle damage classification processing can be performed by a CNN. By way of example, a VGG-CNN was fine-tuned on an ImageNet database using an Unreal Engine dataset. The VGG-CNN was fine-tuned for 13 epochs, used 7,080 training images, and 400 testing images. The results include a training accuracy of 95% and a testing accuracy of 93%. It is noted that saliency visualization data is utilized by the VGG-CNN to make predictions regarding vehicle damage classification. Specifically, saliency visualization data provides the VGG-CNN with relevant pixels in an image such that the VGG-CNN can accurately classify the image based on the provided pixels. For example, FIG. 14 is a compilation of images illustrating vehicle damage saliency visualization training data and FIG. 15 is a compilation of images illustrating vehicle damage saliency visualization testing data.

The system 10 can identify a damaged region in an image directly by using, for example, semantic segmentation. Semantic segmentation provides for classifying each pixel of an image according to a corresponding class being represented by each pixel As such, a vehicle damage region can be identified directly from the image. Specifically, the system 10 classifies each pixel in the image into three classes: 1) a damaged portion of the vehicle class; 2) an undamaged portion of the vehicle class; and 3) a background class while accounting for error metrics (e.g., per pixel cross entropy loss). The system 10 can use an error metric, such as the per-pixel cross-entropy loss function, to measure the error of the neural network 16. The cross-entropy loss function evaluates class predictions for each pixel vector individually and then averages over all pixels.

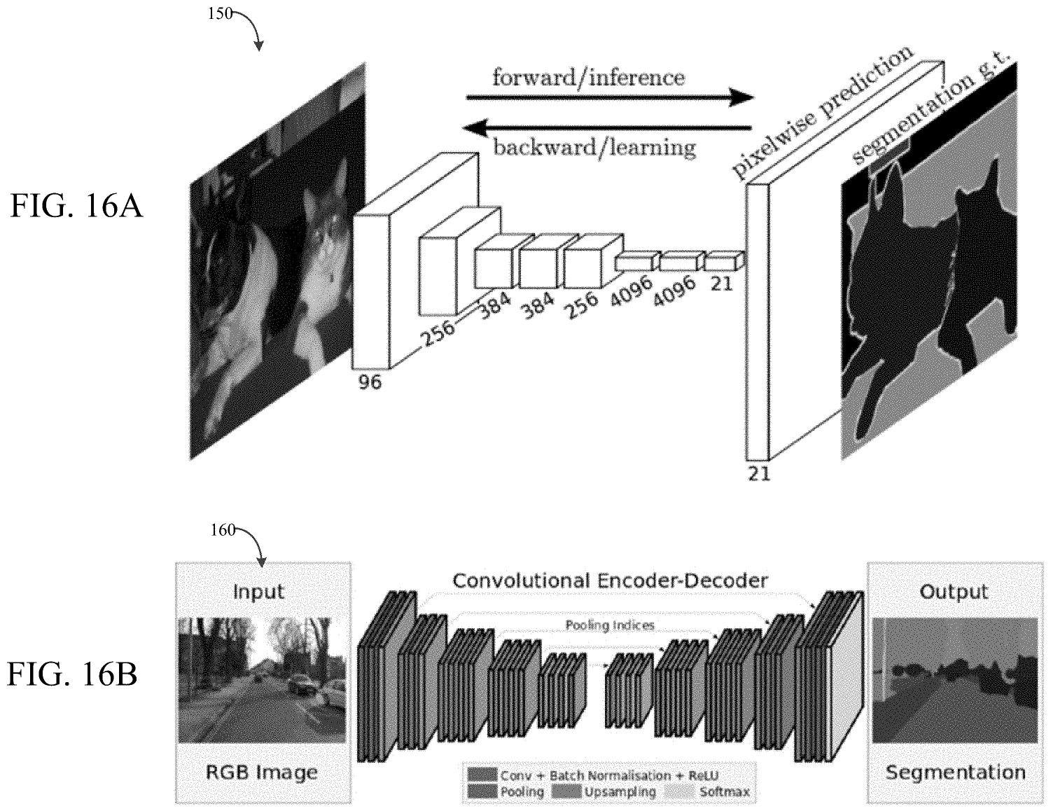

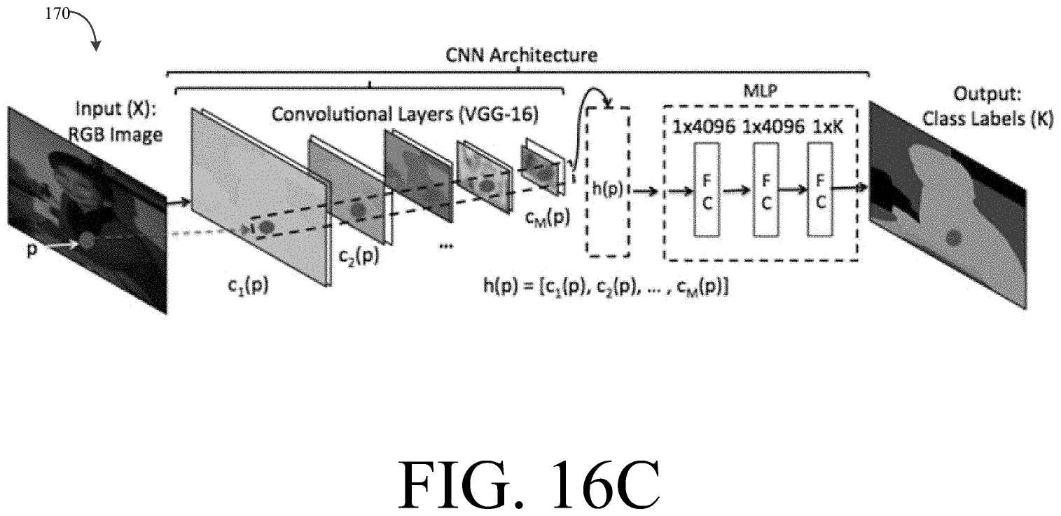

FIGS. 16A-C are diagrams illustrating segmentation processing performed on simulated vehicle data by different neural network models of the system 10 of the present disclosure. Specifically, FIG. 16A is a diagram 150 illustrating segmentation processing performed by a FCN and FIG. 16B is a diagram 160 illustrating segmentation processing performed by a SegNet deep convolutional encoder-decoder architecture for semantic pixel classification. FIG. 16C is a diagram 170 illustrating segmentation processing performed by a PixelNet architecture. PixelNet is characterized by an FCN-like architecture and can separately predict a classification of each pixel. Advantages of utilizing PixelNet for the execution of segmentation processing include, but are not limited to, expedited training and improved classification accuracy.

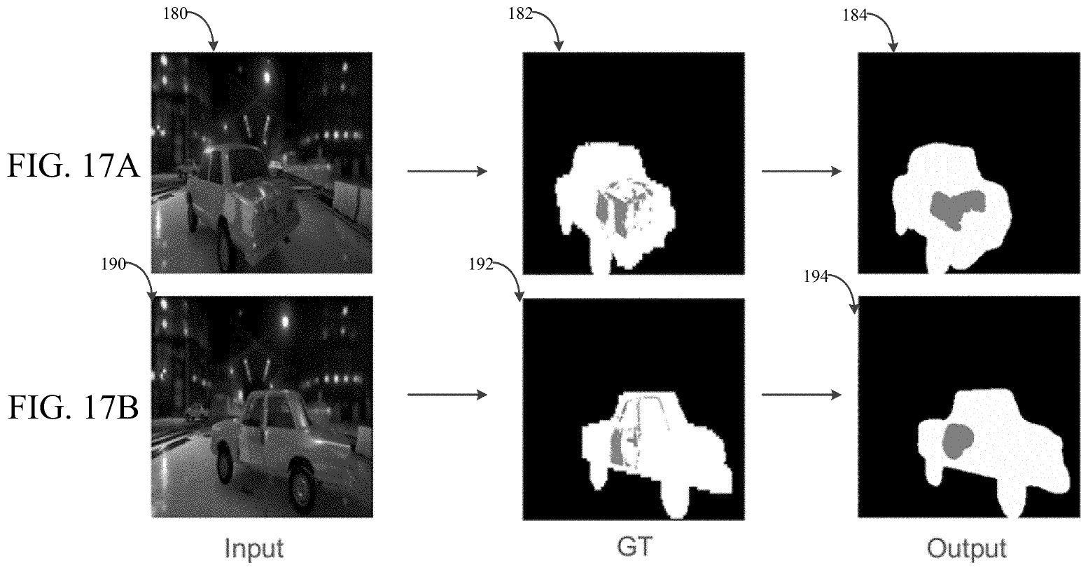

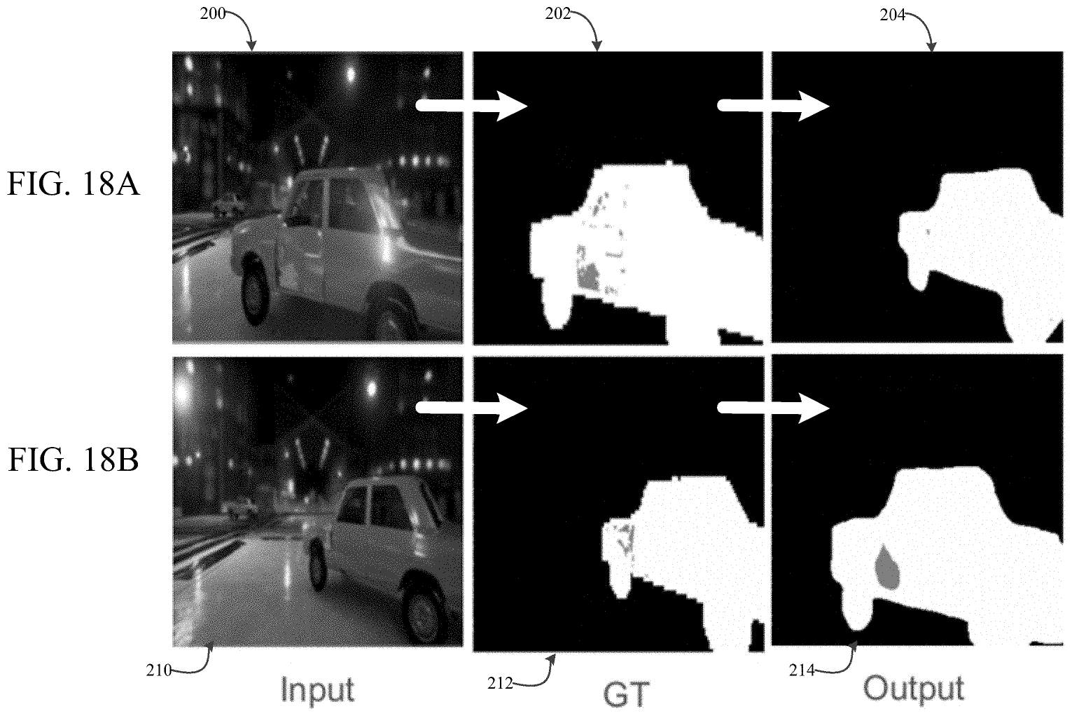

FIGS. 17A-B are images illustrating segmentation processing results for vehicle damage training data based on simulated vehicle damage data inputs according to the system 10 of the present disclosure. Specifically, FIGS. 17A-B show input images 180 and 190, corresponding ground-truth images 182 and 192 and output images 184 and 194. As shown in FIGS. 17A-B, the output images 184 and 194 do not substantially mirror the input images 180 and 190 and the ground truth images 182 and 192. FIGS. 18A-B are images illustrating segmentation processing results for vehicle damage test data based on simulated vehicle damage data inputs according to the system of the present disclosure. Specifically, FIGS. 18A-B show input images 200 and 210, corresponding ground-truth images 202 and 212 and output images 204 and 214. As shown in FIGS. 18A-B, the output images 204 and 214 do not substantially mirror the input images 200 and 210 and the ground truth images 202 and 212.

Results of the above described approach for implementing a computer vision system and method for vehicle damage detection with reinforcement learning will now be discussed. As mentioned above, real datasets and simulated datasets can illustrate vehicle damage including, but not limited to, superficial damage such as a scratch and paint chip and deformation damage such as a dent and extreme deformation. Realistic datasets can be difficult to generate. For example, damage may appear in a vehicle region where the vehicle has not sustained damaged according to an applied damage parameter and deformation damage may not reflect the mesh and skeletal structure (i.e., bone structure) of the vehicle. Generated datasets should be scalable and realistic. However, simulated datasets via Unreal Engine are difficult to scale because of the required generation of a new physics asset and a new skeleton asset for each vehicle component.

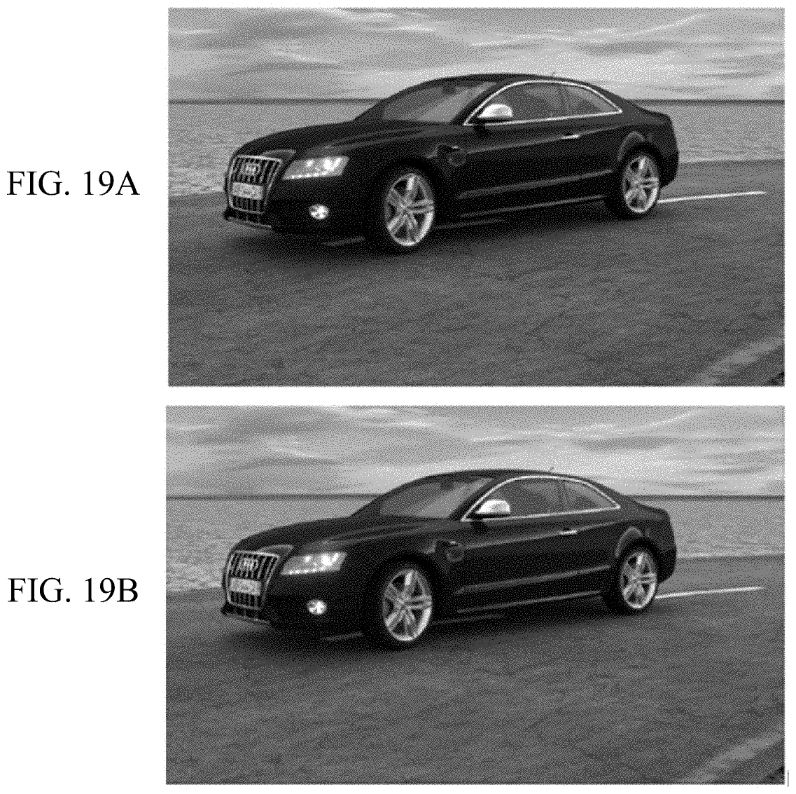

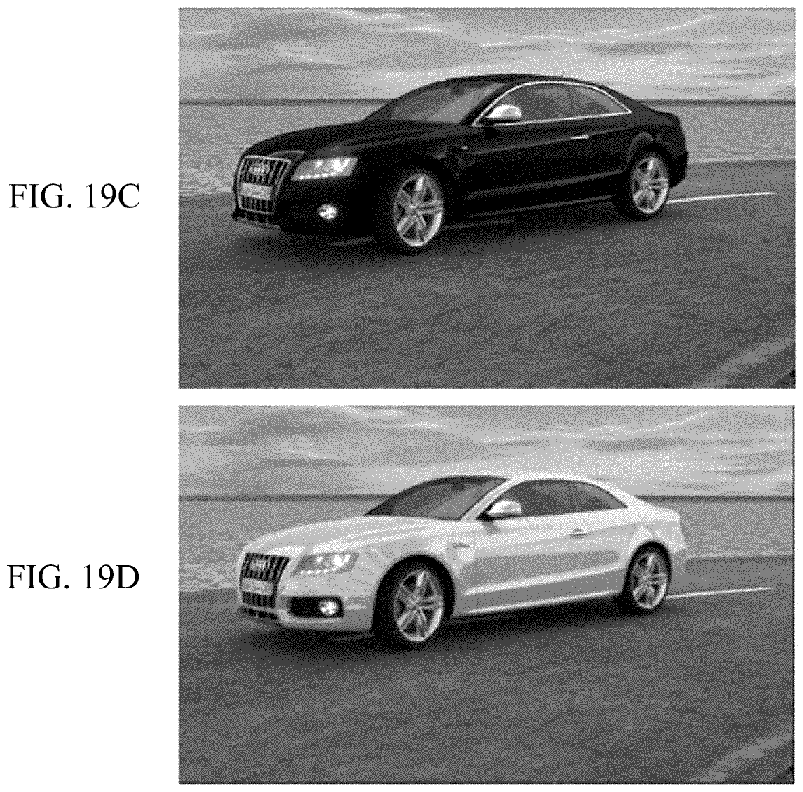

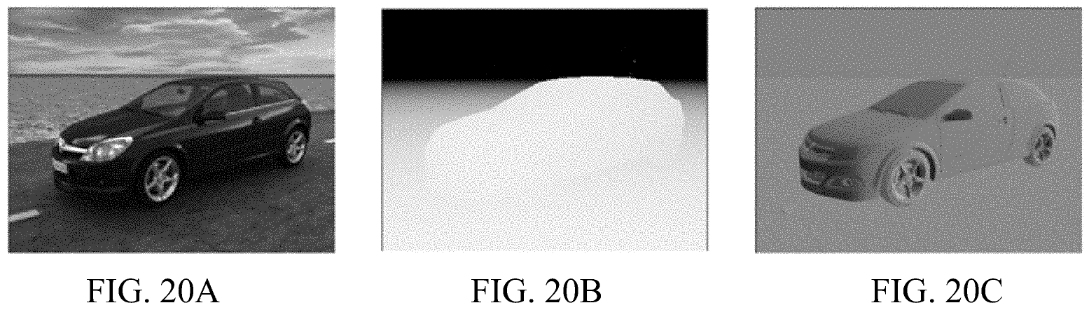

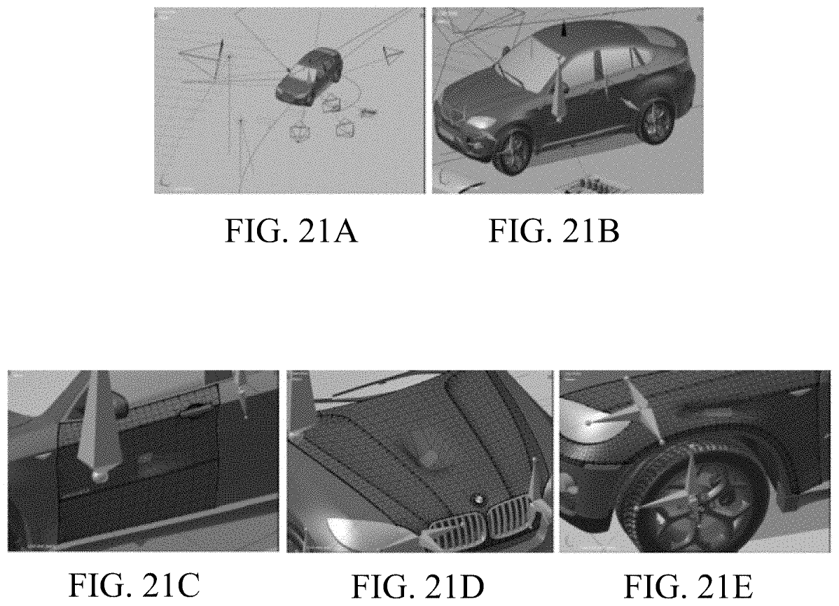

By way of another example, simulated datasets can also be generated by utilizing Blender simulation software. FIGS. 19A-D are images illustrating a simulated vehicle generated by the dataset generation module 14 of FIG. 2 via the Blender simulation software. It should be understood that Blender can also obtain surface normal and depth maps. For example, FIGS. 20A-C are images illustrating generated surface normal and depth maps of a vehicle.

FIGS. 21A-E are images illustrating a simulated vehicle and simulated damage data generated by the system 10 of the present disclosure via Blender. Specifically, FIGS. 21A and 21B depict a setup scene and a three-dimensional computer-aided design (3D CAD) model of a simulated vehicle. In addition, FIGS. 21C-E respectively illustrate damaged sustained by the vehicle 3D CAD model to the driver side door, the hood and the driver side fender. Blender can generate deformation, such as dents, semi-manually in a scalable manner utilizing, for example, python scripts. The deformation can be generalizable to multiple vehicle types and views thereof. For each component of the 3D CAD model and for each face in a mesh, the system 10 moves each face in a mesh by 0.05 units into the vehicle 3D CAD model to form a deformation. This can be performed for each face of the vehicle 3D CAD model. The system 10 can render an image of a dataset in 320×240 resolution in approximately one minute and generates segmentation maps based on the rendered image. The system 10 then assigns a center of a face in world coordinates with respect to the vehicle 3D CAD model. These coordinates can be warped into world coordinates with respect to a world origin. Subsequently, the warped coordinates can be warped into a 2D image utilizing a camera transformation matrix.

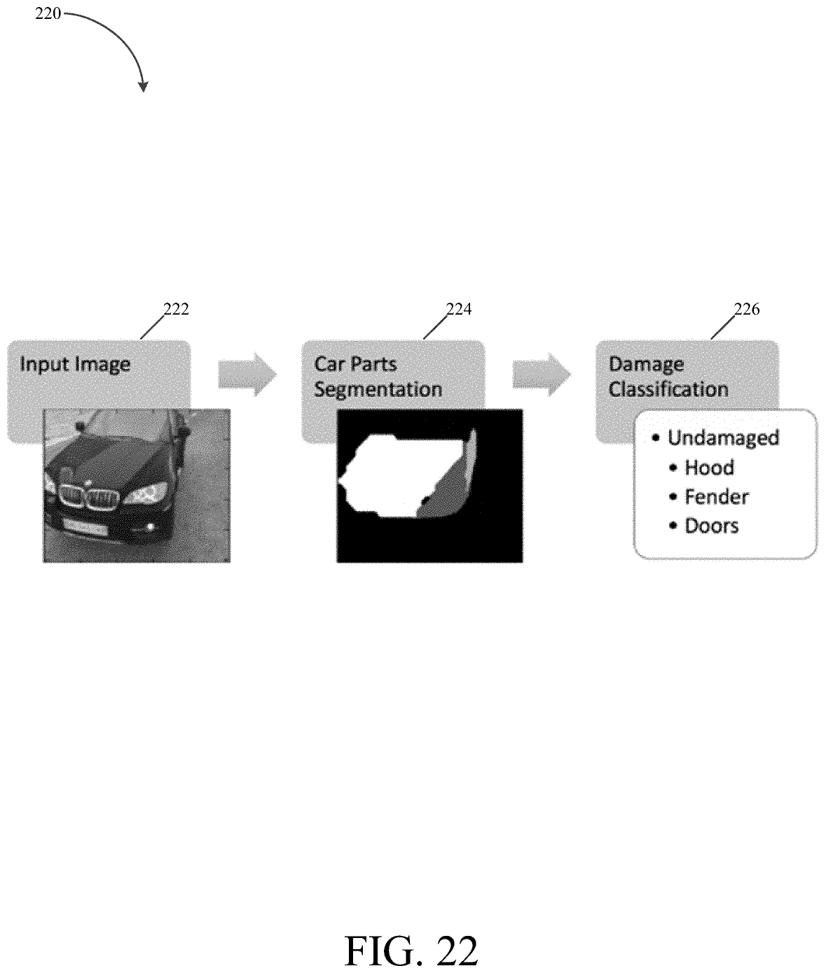

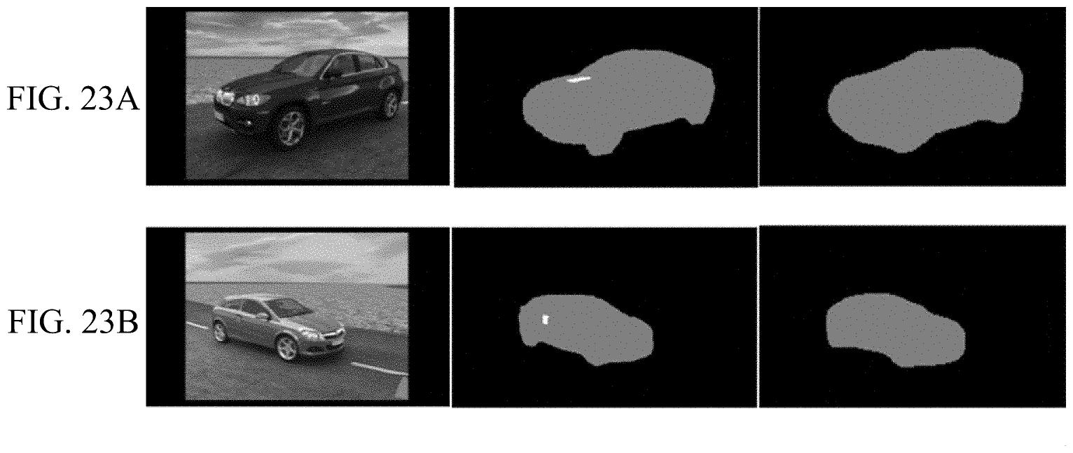

FIG. 22 is a flowchart 220 illustrating vehicle damage detection processing performed by the system 10 of the present disclosure on Blender generated simulated data. In step 222, the system 10 receives a simulated input image of a vehicle. Then, in step 224, the system 10 segments the simulated input image of the vehicle into corresponding components of the vehicle. For example, the system 10 can segment the simulated input image to distinguish the hood, fender and door components of the vehicle. Lastly, in step 226, the system 10 crops each segmented component along with its context from the obtained segmentation, and classifies each component based on a degree of damage (e.g., undamaged, mildly damaged, and extremely damaged). For example, the system 10 can classify a degree of damage of any of the segmented hood, fender and door vehicle components.

The system 10 can utilize the PixelNet architecture to segment vehicle components. FIGS. 23A-B are sets of images respectively illustrating segmentation training set data and testing set data. As discussed above, PixelNet is characterized by an FCN like architecture and can separately predict a classification of each pixel. Advantages of utilizing PixelNet for the execution of segmentation processing include, but are not limited to, expedited training and improved accuracy. It should be understood that PixelNet utilizes a uniform sampling of pixels which can yield an imbalance between a number of background pixels and vehicle pixels resulting in the exclusion of damaged vehicle pixels. Accordingly, in this approach the sampling scheme requires modification and retraining.

Alternatively, segmentation processing can be performed with a U-Net-CNN. It is noted that a U-Net-CNN works well with small datasets. Advantageously, the segmentation processing provides for identifying a damaged vehicle component instead of a damaged vehicle region in two steps via vehicle component segmentation and damage severity classification. The vehicle component segmentation can be classified into six classes including a vehicle left front door, a vehicle right front door, a vehicle left front fender, a vehicle right front fender, a vehicle hood and a background. Damage severity classification can be classified for each vehicle component segmentation class according to one of undamaged, mildly damaged and extremely damaged by cropping each vehicle component along with its corresponding context from the obtained segmentation.

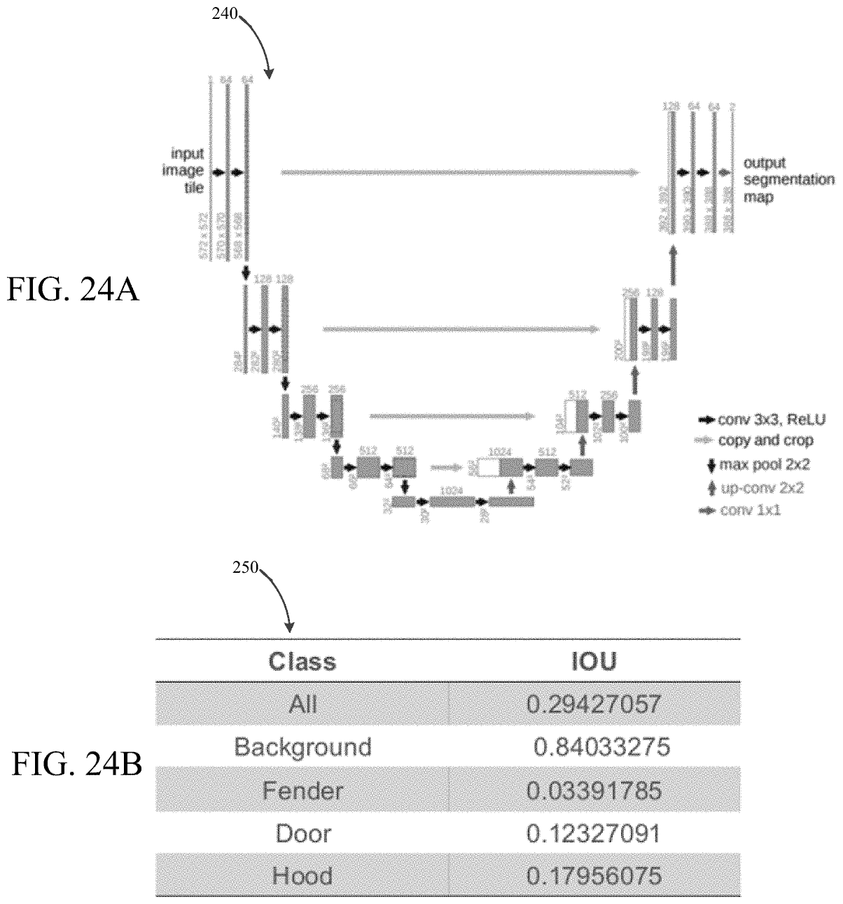

FIG. 24A is a diagram 240 illustrating vehicle component segmentation processing utilizing a U-Net-CNN. FIG. 24B is a chart 250 illustrating results of the vehicle component segmentation processing performed by the U-Net-CNN architecture of FIG. 24A. The chart 250 illustrates the intersection over union (IoU) for each of the segments of the simulated input image. The IoU is a metric that provides for evaluating how similar a predicted result is to the ground truth.

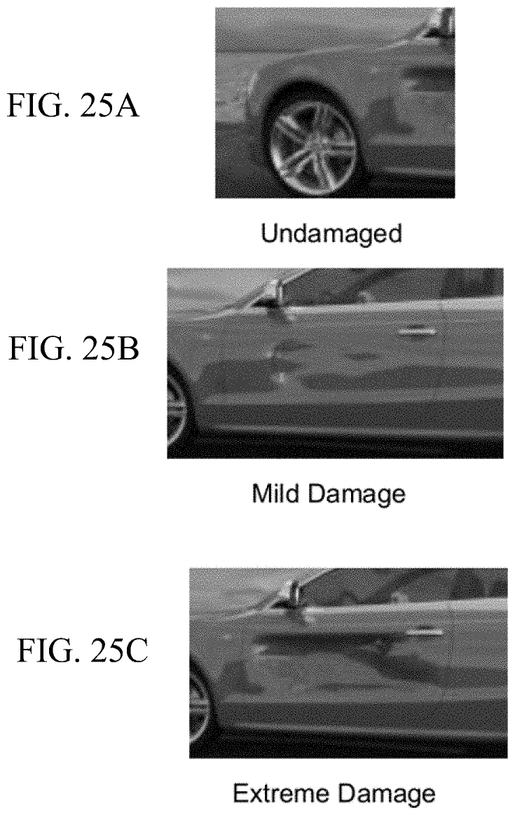

FIGS. 25A-C are images illustrating vehicle damage classifications. Specifically, FIGS. 25A-C illustrate increasingly severe damage sustained by a vehicle. For example, FIG. 25A illustrates an undamaged vehicle whereas FIGS. 25B and 25C respectively illustrate mild damage sustained by the vehicle and extreme damage sustained by the vehicle.

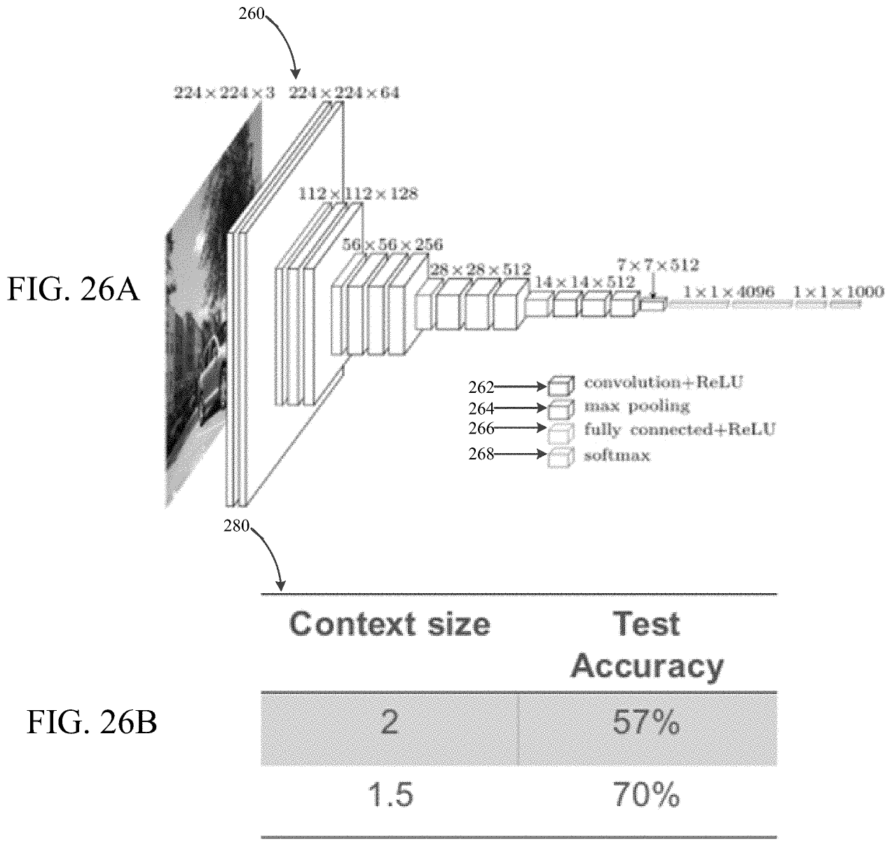

FIG. 26A is a diagram 260 illustrating a VGG-CNN for performing vehicle damage classification processing. As shown in FIG. 26A, a VGG-CNN, is executed over a simulated vehicle input image to yield features of the image. The VGG-CNN and additional convolution layers progressively decrease a size of the input image at each layer. The layers include one or more convolution layers with ReLU(s) 262, one or more maximum pooling layers 264, one or more fully connected layers with ReLU(s) 266, and one or more softmax layers 268 for further classification. Each layer can apply an operation to a signal from an input node. The result produces an output signal that is fed-forward to a next filter or process in a next layer of the VGG-CNN, or the result can be transformed into an output node. It should be understood that other layers, filters, and/or processes can by utilized by the VGG CNN. FIG. 26B is a chart 280 illustrating results of the vehicle damage classification processing performed by the VGG-CNN of FIG. 26A. The chart denotes test accuracy of the VGG-CNN in view of context size.

Results of the above described approach for implementing a computer vision system and method for vehicle damage detection with reinforcement learning will now be discussed. As described above, real datasets and simulated datasets can illustrate vehicle damage including, but not limited to, superficial damage such as a scratch and a paint chip and deformation damage such as a dent and an extreme deformation. Real datasets provide acceptable vehicle damage classification results (i.e., whether a vehicle has sustained damage). It should be understood that vehicle localization damage (e.g., front, side and/or rear) results and the severity classification (e.g., mild, moderate and/or extreme) results based on real datasets can be improved. Simulated datasets provide for encouraging vehicle damage classification. It should be understood that simulated datasets are more cumbersome than real datasets because of the plurality of variables required to simulate the real world. For example, simulated datasets necessitate automated or manual generation of particular damage types (e.g., dents and extreme deformation damage) and long rendering times. Further, simulated datasets render images in low resolution and require a user to have experience with simulation software (e.g., at least one of Blender and Unreal Engine) to efficiently simulate the datasets. Additionally, domain transfer to real images requires dense labels on real data.

Accordingly, the computer vision system and method for vehicle damage detection with reinforcement learning can be improved upon by building a structured real image dataset comprising real images illustrating vehicle damage and utilizing multiple input images illustrating vehicle damage to improve vehicle damage detection and classification. The real world dataset could be generated via collected data on the internet based on structured search strings wherein labels/annotations for the collected data could be provided by Amazon Mechanical Turk. Additionally, bounding box based detection could be implemented to improve vehicle damage detection and classification. It is noted that the training of a CNN is less difficult to implement on Keras in comparison to older frameworks (e.g., Caffe).

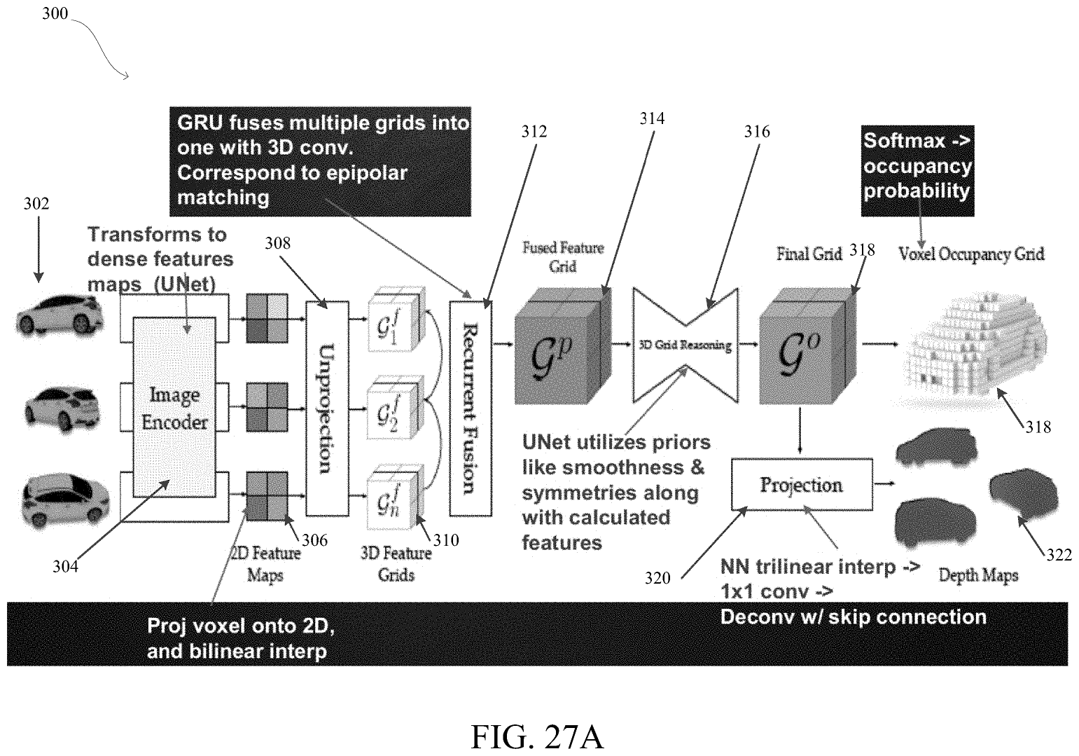

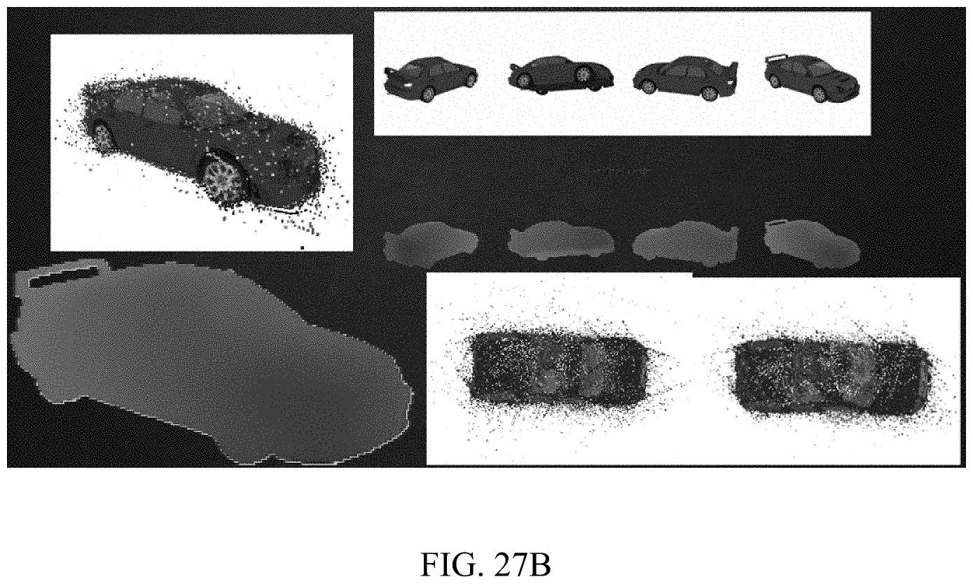

FIG. 27A is a diagram illustrating processing steps carried out by an embodiment of the system 300 of the present disclosure for reconstructing a vehicle from one or more digital images. The system 300 can select a fewest number of viewpoints from one or more digital images, and reconstruct a vehicle in the digital images in a computer system. The reconstruction can be, for example, a CAD model, a voxel occupancy grid, a depth map, etc. The system 300 can include one or more neural networks, such as, for example, a liquid state machine (LSM). The system 300 receives one or more inputs 302 via an image encoder 304. The inputs 302 can comprise one or more digital images showing different viewpoints of a vehicle. The image encoder 304 transforms the digital images into dense feature maps using a neural network, such as a UNet. The image encoder 304 generates 2D feature maps 306 that are fed into an un-projection system 308, which generates 3D feature grids 310. The 3D feature grids 310 are then fed into a recurrent fusion model 312, which fuses multiple grids into one with a 3D convergence to generate a fused feature grid 314.

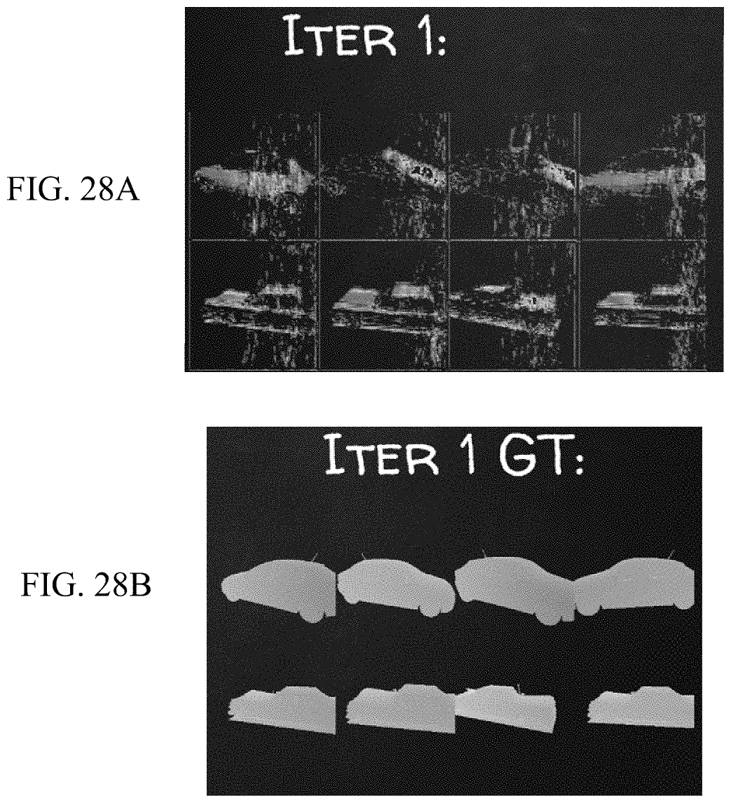

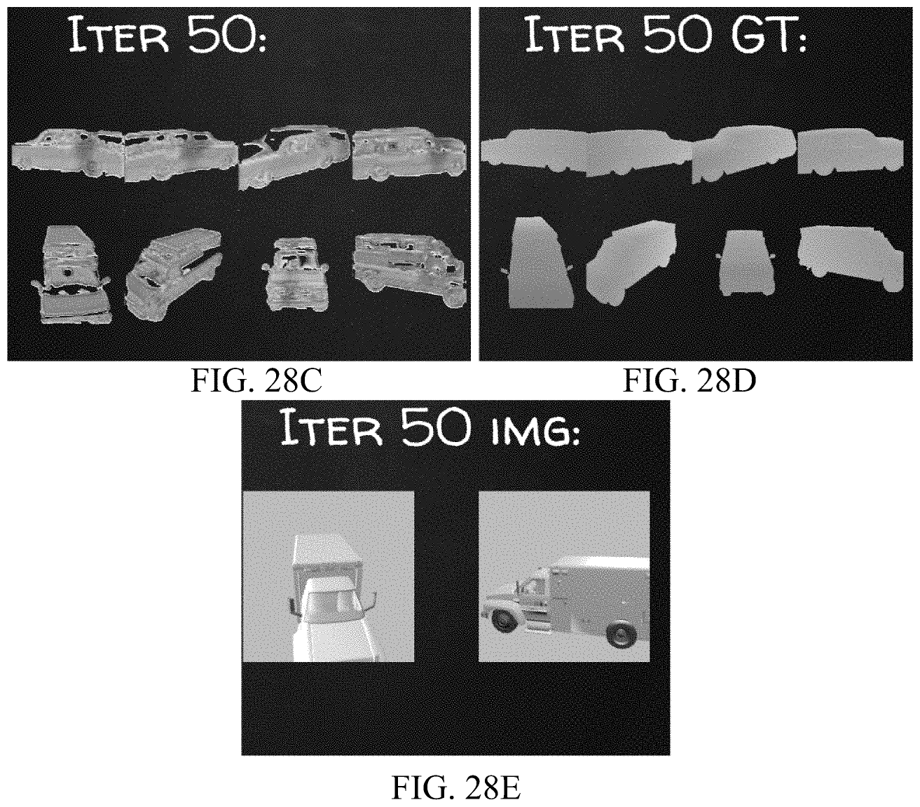

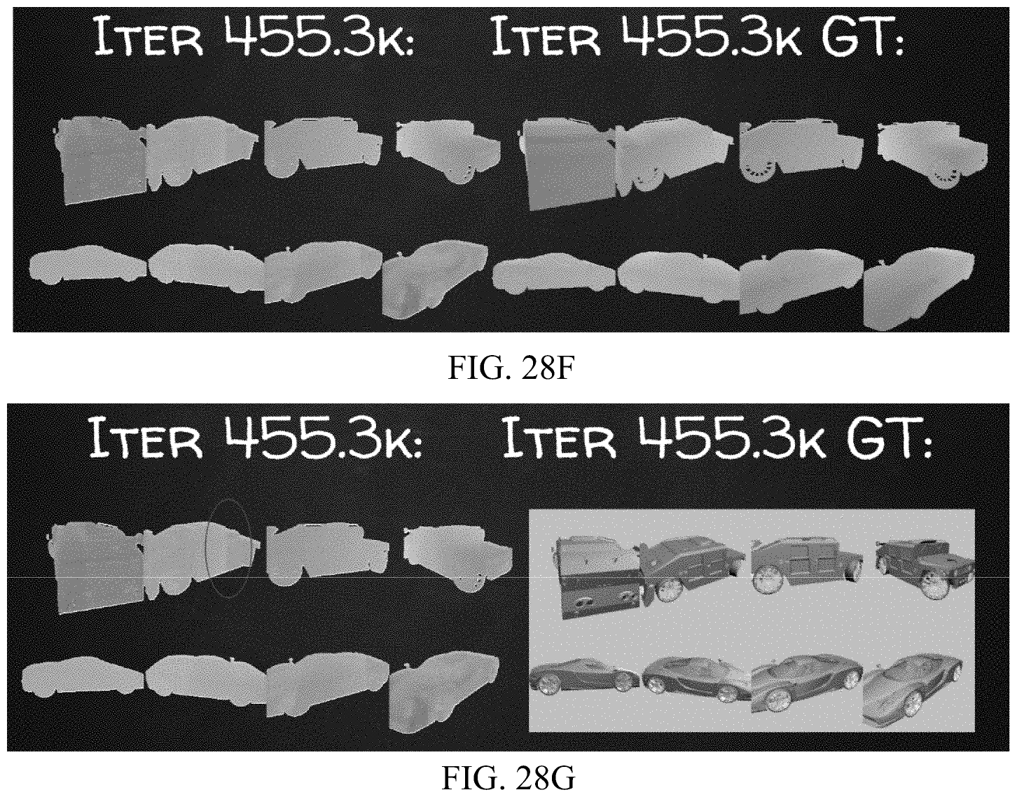

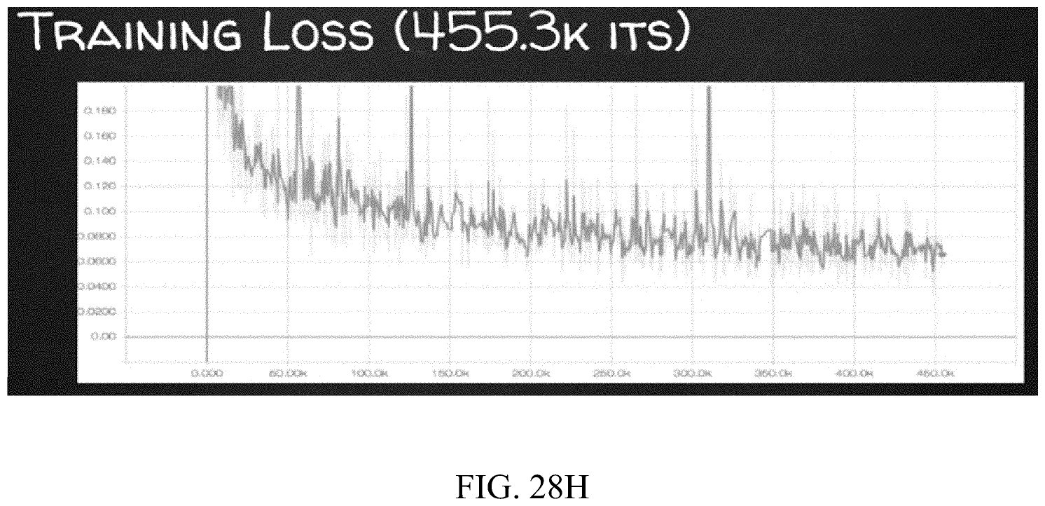

The fused feature grid 314 is fed into a 3D grid reasoning model 316, which utilizes priors such as smoothness and symmetries along with calculated features, to generate a final grid 318. The 3D grid reasoning model 316 can be a neural network, such as a UNet. The final grid 318 can be displayed as a voxel occupancy grid 318, or can be fed into a projection model 320, which generates one or more depth maps 322. For example, FIG. 27B illustrates depth maps generated by the system of FIG. 27A. FIGS. 28A-G are illustrations showing example results of the system 300. FIG. 28H is a graph illustrating training loss corresponding to FIGS. 28F-G. It is noted that increasing the number of views (e.g., from 4 to 8 per model) can lead to a faster convergence. Further, grid size and a number of views does not affect final loss and visual results of depth maps.

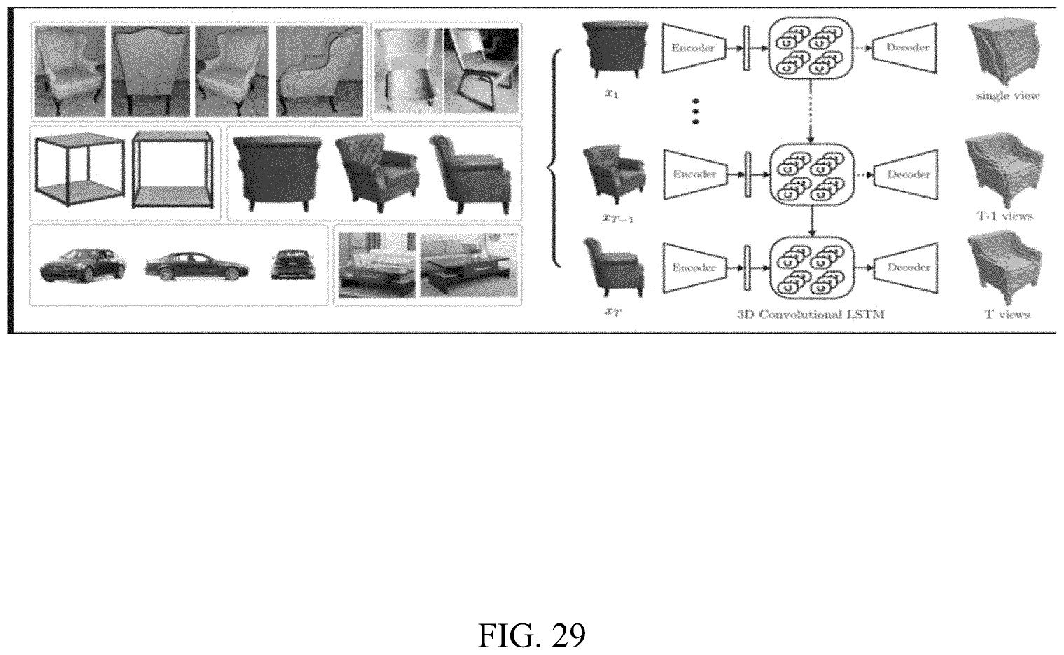

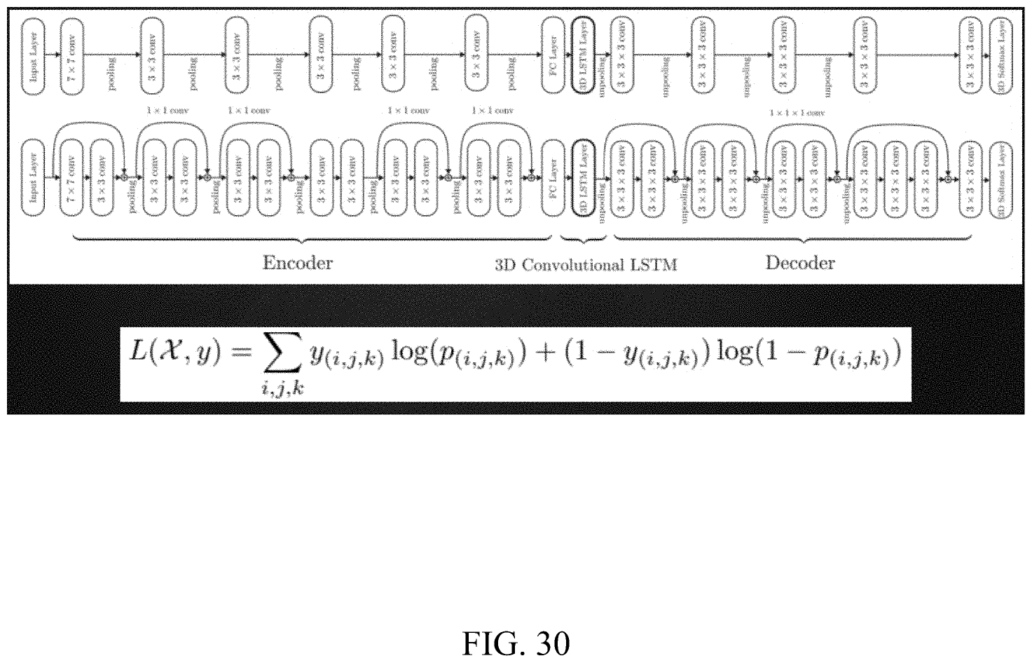

In another example, the system 300 can utilize a 3D recurrent reconstruction neural network (3D-R2N2) for 3D objection reconstruction. FIGS. 29 and 30 are diagrams illustrating an architecture of the 3D-R2N2. The 3D-R2N2 takes one or more images from arbitrary viewpoints and outputs a 3D occupancy grid. The 3D-R2N2 requires minimal supervision and does not require image annotations or segmentation masks.

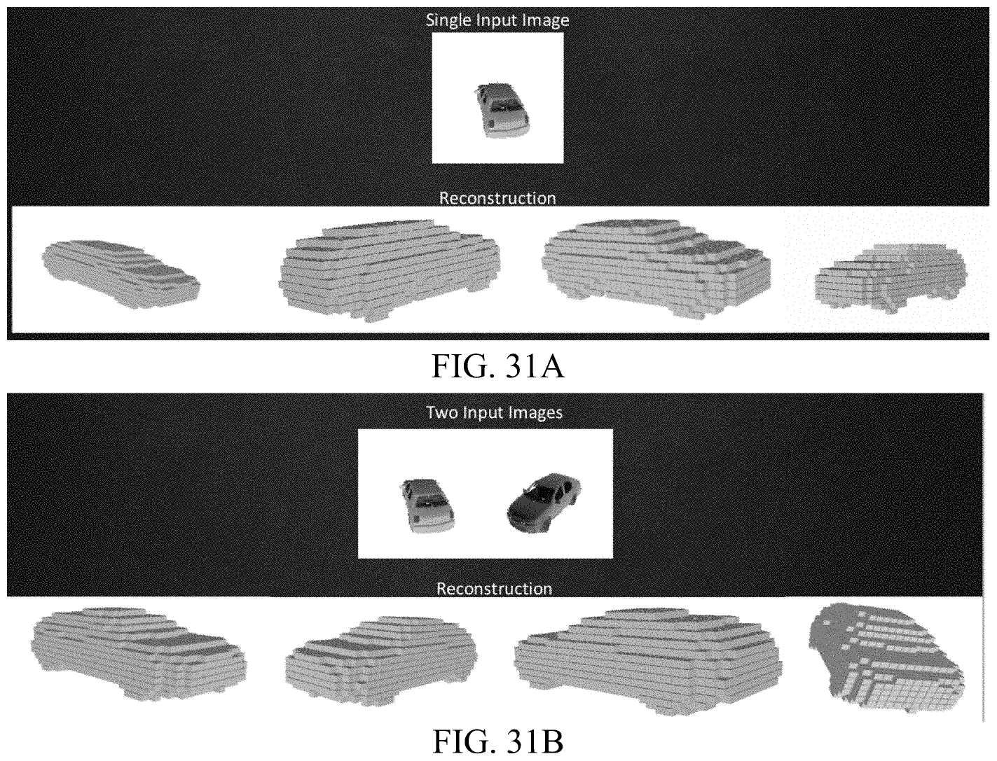

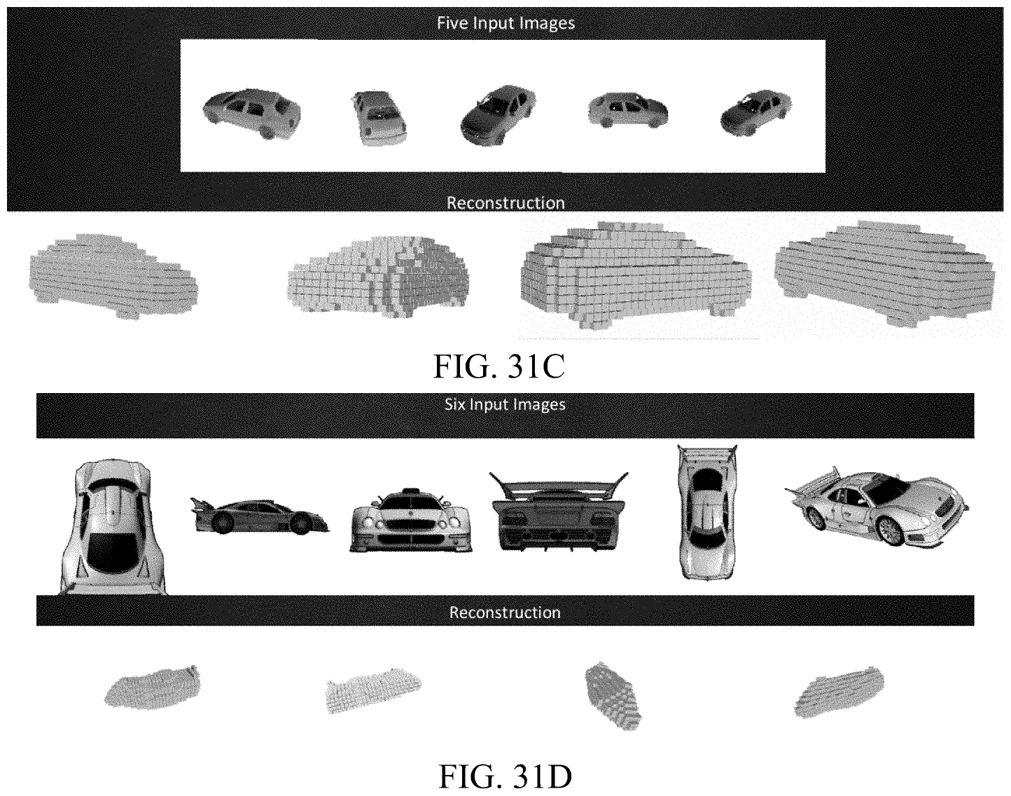

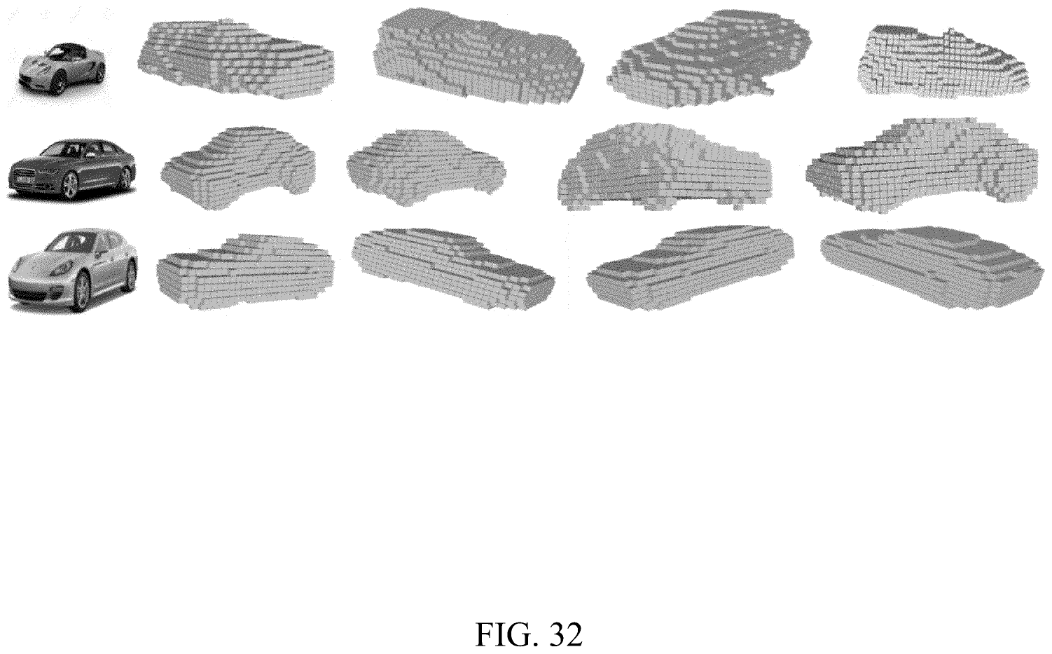

FIGS. 31A-D are diagrams of voxel reconstructions generated by the 3D-R2N2 from one or more input images. Specifically, FIG. 31A shows voxel reconstructions generated by the 3D-R2N2 from one input image and FIG. 31B shows voxel reconstructions generated by the 3D-R2N2 from two input images. Additionally, FIG. 31C shows voxel reconstructions generated by the 3D-R2N2 from five input images and FIG. 31D shows voxel reconstructions generated by the 3D-R2N2 from six input images. FIG. 32 is a diagram illustrating a set of illustrations of voxel reconstructions generated by the 3D-R2N2 from a single real image. It is noted that a recommended setting for voxel reconstructions is a resolution of 256×256×256 or higher.

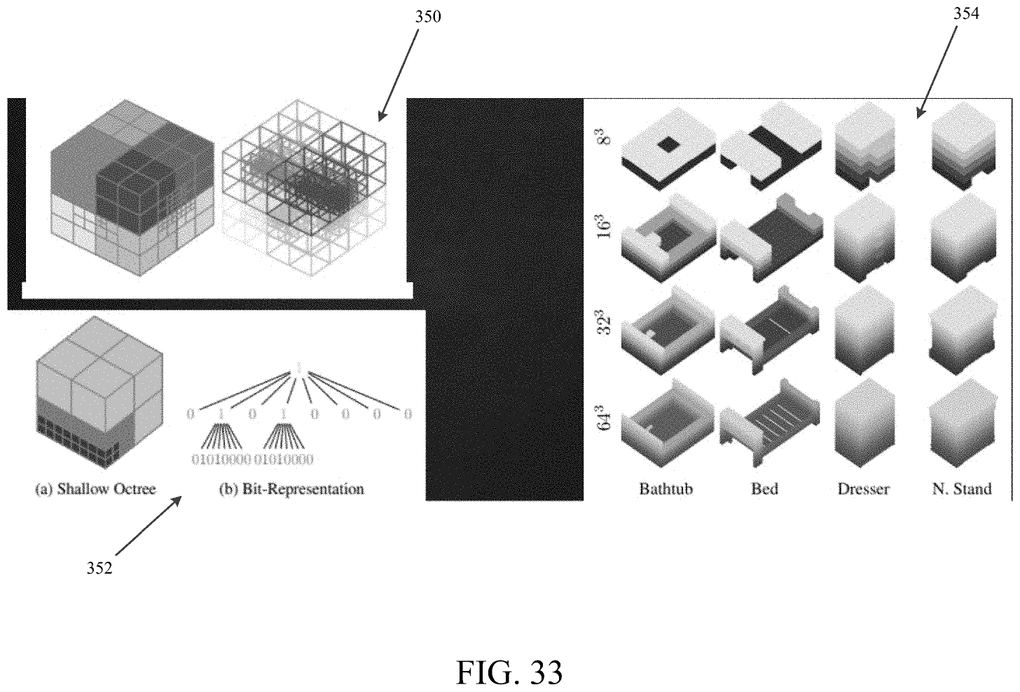

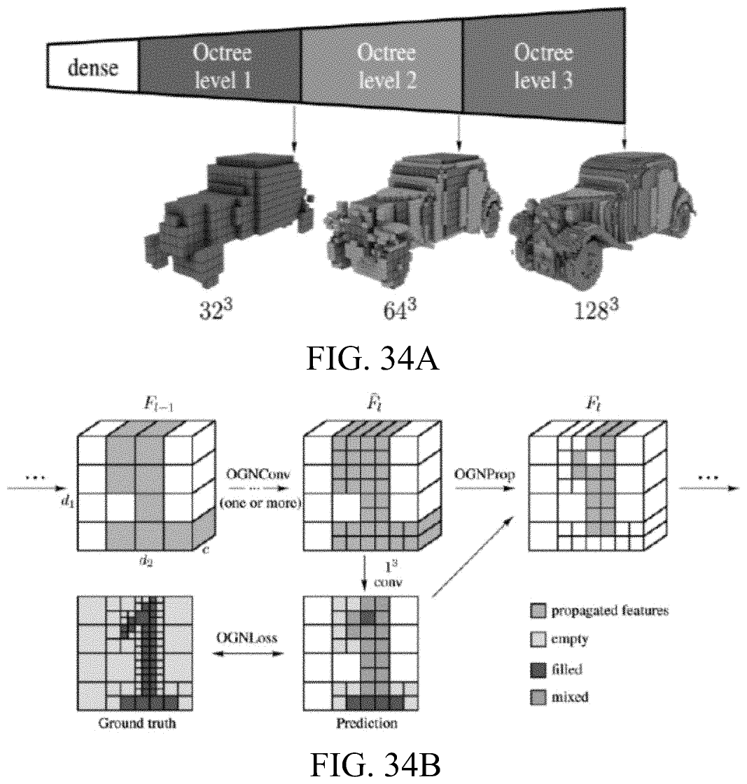

In some embodiments, an Octree Generation Network (OctNet) can be utilized by the system 300 to generate 3D objection reconstructions. FIG. 33 is a diagram illustrating an OctNet. Specifically, FIG. 33 shows a hybrid-grid-octree data structure 350, a bit representation 352, and voxelized 3D shapes from a ModelNet 10 network 354. FIGS. 34A-B are diagrams illustrating processing performed by the OctNet of FIG. 33. Specifically, FIG. 34A shows different levels of 3D objection reconstructions by the OctNet and FIG. 34B illustrates processing performed by the OctNet (e.g., the flow of propagated features, empty features, filled features, and mixed features).

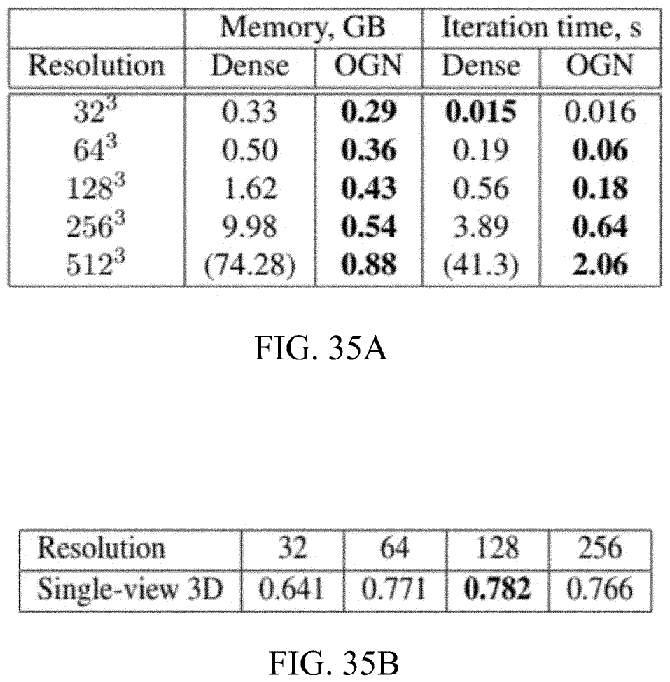

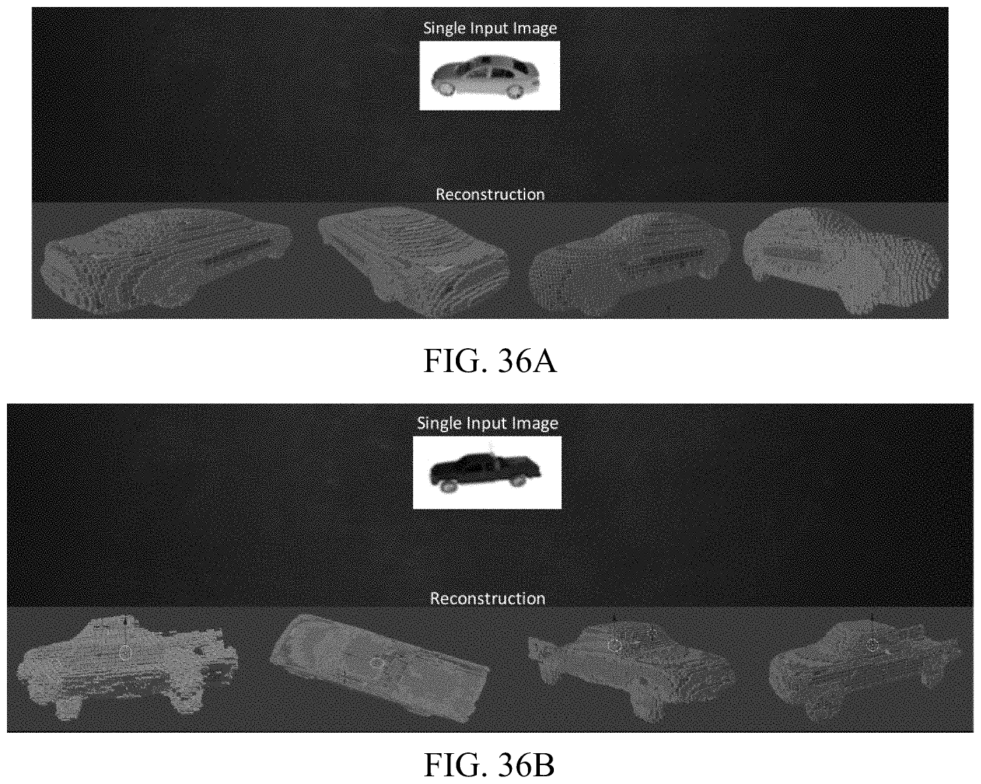

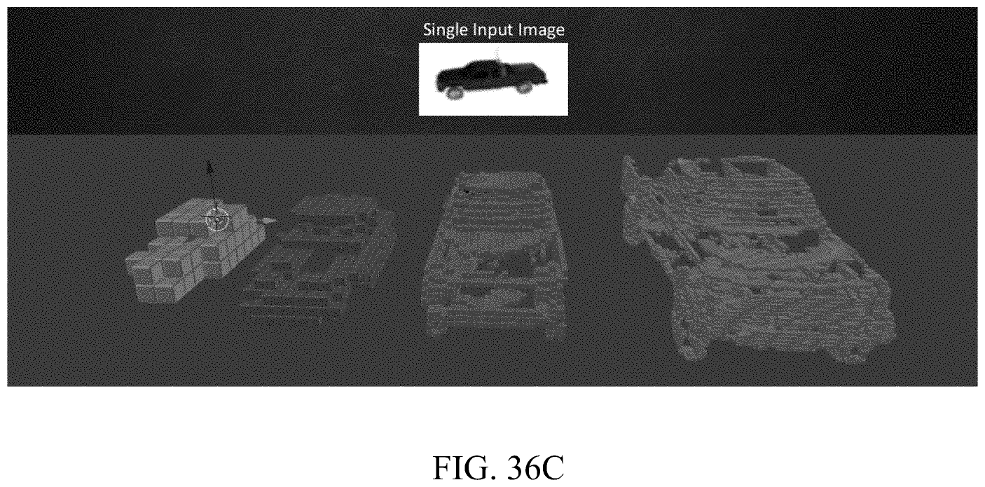

FIGS. 35A-B are charts illustrating performance benefits of the OctNet. For example, FIG. 35A shows the memory consumption and iteration time of the OctNet against a dense network. As shown in FIG. 35A, the OctNet is more efficient in memory and computation times. FIG. 35B shows single-image 3D reconstruction results on ShapeNet-cars. FIGS. 36A-C are diagrams illustrating voxel reconstructions generated by the OctNet of FIG. 33 from a single input image.

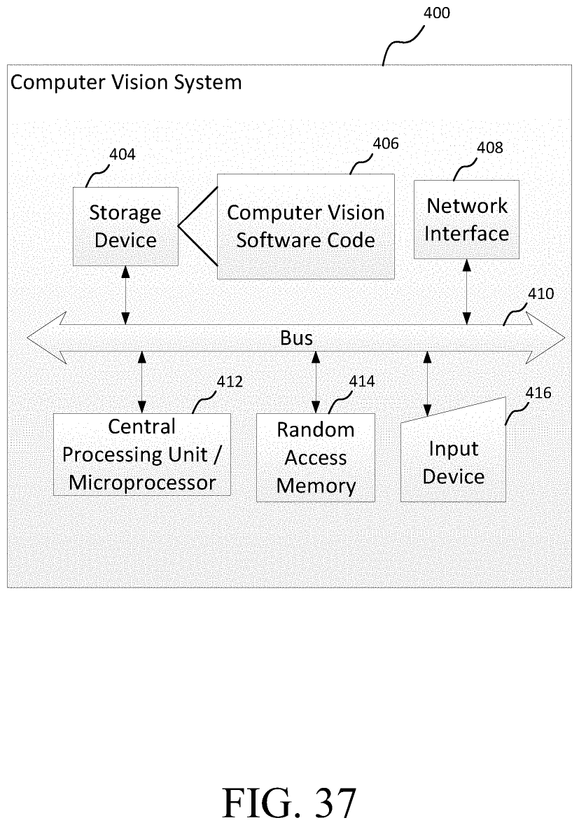

FIG. 37 is a diagram showing hardware and software components of a computer system 400 on which the system of the present disclosure can be implemented. The computer system 400 can include a storage device 404, computer vision software code 406, a network interface 408, a communications bus 410, a central processing unit (CPU) (microprocessor) 412, a random access memory (RAM) 414, and one or more input devices 416, such as a keyboard, mouse, etc. The computer system 400 could also include a display (e.g., liquid crystal display (LCD), cathode ray tube (CRT), etc.). The storage device 404 could comprise any suitable, computer-readable storage medium such as disk, non-volatile memory (e.g., read-only memory (ROM), eraseable programmable ROM (EPROM), electrically-eraseable programmable ROM (EEPROM), flash memory, field-programmable gate array (FPGA), etc.). The computer system 400 could be a networked computer system, a personal computer, a server, a smart phone, tablet computer etc. It is noted that the computer system 400 need not be a networked server, and indeed, could be a stand-alone computer system.

The functionality provided by the present disclosure could be provided by computer vision software code 406, which could be embodied as computer-readable program code stored on the storage device 404 and executed by the CPU 412 using any suitable, high or low level computing language, such as Python, Java, C, C++, C#, .NET, MATLAB, etc. The network interface 408 could include an Ethernet network interface device, a wireless network interface device, or any other suitable device which permits the server computer system 400 to communicate via the network. The CPU 412 could include any suitable single-core or multiple-core microprocessor of any suitable architecture that is capable of implementing and running the computer vision software code 406 (e.g., Intel processor). The random access memory 414 could include any suitable, high-speed, random access memory typical of most modern computers, such as dynamic RAM (DRAM), etc.

Having thus described the system and method in detail, it is to be understood that the foregoing description is not intended to limit the spirit or scope thereof. It will be understood that the embodiments of the present disclosure described herein are merely exemplary and that a person skilled in the art can make any variations and modification without departing from the spirit and scope of the disclosure. All such variations and modifications, including those discussed above, are intended to be included within the scope of the disclosure.

What is claimed is:

1. A computer vision system for vehicle damage detection comprising:
a memory; and
a processor in communication with the memory, the processor:
generating a dataset,
training a neural network with a plurality of images of the dataset to learn to detect an attribute of a vehicle present in an image of the dataset and to classify at least one feature of the detected attribute, and
detecting the attribute of the vehicle and classifying the at least one feature of the detected attribute by the trained neural network.

2. The system of claim 1, wherein the processor generates a real dataset based on labeled digital images, each labeled digital image being indicative of an undamaged vehicle or a damaged vehicle.

3. The system of claim 1, wherein the processor generates a simulated dataset by:
generating components of a simulated vehicle,
linking each component to generate a simulated vehicle,
simulating an external force on the simulated vehicle to generate damage to the simulated vehicle,
identifying and labeling the generated damage to the simulated vehicle, and
storing the damaged simulated vehicle as an image of the simulated dataset.

4. The system of claim 1, wherein the neural network is a convolutional neural network (CNN) or a fully convolutional network (FCN).

5. The system of claim 1, wherein the processor generates a simulated dataset including a plurality of images of a reconstructed damaged vehicle based on a plurality of digital images of the damaged vehicle by:
selecting digital images indicative of a fewest number of viewpoints from the plurality of digital images of the damaged vehicle,
transforming the digital images by an encoder to generate two-dimensional dense feature maps utilizing a second neural network,
generating a plurality of three-dimensional feature grids based on the two-dimensional dense feature maps utilizing an unprojection model,
generating a three-dimensional fused feature grid by fusing the plurality of three-dimensional feature grids utilizing a recurrent fusion model,
generating a three-dimensional final grid based on prior constraints and determined features utilizing the second neural network, and
displaying the three-dimensional final grid as the reconstructed damaged vehicle.

6. The system of claim 5, wherein the reconstructed damage vehicle is one of a computer aided design (CAD) model or a voxel occupancy grid.

7. The system of claim 5, wherein the processor
generates one or more depth maps based on the three-dimensional final grid utilizing a projection model, and
displays the one or more depth maps as the reconstructed damaged vehicle.

8. The system of claim 5, wherein the second neural network is a convolutional neural network (CNN) or a liquid state machine (LSM).

9. The system of claim 1, wherein the vehicle is one of an automobile, a truck, a bus, a motorcycle, an all-terrain vehicle, an airplane, a ship, a boat, a personal water craft, or a train.

10. The system of claim 1, wherein the processor trains the neural network to detect damage to the vehicle present in the image and to classify a location of the detected damage and a severity of the detected damage, the damage being at least one of a scratch, a scrape, a crack, a paint chip, a puncture, a dent, a deployed airbag, a deformation, a broken axle, a twisted frame or a bent frame.

11. The system of claim 10, wherein the location of the detected damage is at least one of a front, a rear or a side of the vehicle and the severity of the detected damage is based on predetermined damage sub-classes.

12. The system of claim 10, wherein the processor trains the neural network to learn to detect damage to the vehicle present in the image and to classify the location of the detected damage and the severity of the detected damage by:
segmenting components of the vehicle, and
detecting at least one segmented component of the vehicle indicative of damage.

13. The system of claim 10, wherein the processor trains the neural network to learn to detect damage to the vehicle present in the image and to classify the location of the detected damage and the severity of the detected damage by:
segmenting regions of the image based on saliency visualization data, and
detecting at least one segmented region of the image indicative of damage to the vehicle.

14. A method for vehicle damage detection by a computer vision system, comprising the steps of:
generating a dataset,
training a neural network with a plurality of images of the dataset to learn to detect an attribute of a vehicle present in an image of the dataset and to classify at least one feature of the detected attribute, and
detecting the attribute of the vehicle and classifying the at least one feature of the detected attribute by the trained neural network.

15. The method of claim 14, further comprising the step of generating a real dataset based on labeled digital images, each labeled digital image being indicative of an undamaged vehicle or a damaged vehicle.

16. The method of claim 14, further comprising the steps of generating a simulated dataset by:
generating components of a simulated vehicle,
linking each component to generate a simulated vehicle,
simulating an external force on the simulated vehicle to generate damage to the simulated vehicle,
identifying and labeling the generated damage to the simulated vehicle, and
storing the damaged simulated vehicle as an image of the simulated dataset.

17. The method of claim 14, wherein the neural network is a convolutional neural network (CNN) or a fully convolutional network (FCN).

18. The method of claim 14, further comprising the steps of generating a simulated dataset including a plurality of images of a reconstructed damaged vehicle based on a plurality of digital images of the damaged vehicle by:
selecting digital images indicative of a fewest number of viewpoints from the plurality of digital images of the damaged vehicle,
transforming the digital images by an encoder to generate two-dimensional dense feature maps utilizing a second neural network,
generating a plurality of three-dimensional feature grids based on the two-dimensional dense feature maps utilizing an unprojection model,
generating a three-dimensional fused feature grid by fusing the plurality of three-dimensional feature grids utilizing a recurrent fusion model,
generating a three-dimensional final grid based on prior constraints and determined features utilizing the second neural network, and
displaying the three-dimensional final grid as the reconstructed damaged vehicle.

19. The method of claim 18, wherein the reconstructed damage vehicle is one of a computer aided design model or a voxel occupancy grid.

20. The method of claim 18, further comprising the steps of:
generating one or more depth maps based on the three-dimensional final grid utilizing a projection model, and
displaying the one or more depth maps as the reconstructed damaged vehicle.

21. The method of claim 18, wherein the second neural network is a convolutional neural network (CNN) or a liquid state machine (LSM).

22. The method of claim 14, wherein the vehicle is one of an automobile, a truck, a bus, a motorcycle, an all-terrain vehicle, an airplane, a ship, a boat, a personal water craft, or a train.

23. The method of claim 14, further comprising the steps of training the neural network to detect damage to the vehicle present in the image and to classify a location of the detected damage and a severity of the detected damage, the damage being at least one of a scratch, a scrape, a crack, a paint chip, a puncture, a dent, a deployed airbag, a deformation, a broken axle, a twisted frame or a bent frame.

24. The method of claim 23, wherein the location of the detected damage is at least one of a front, a rear or a side of the vehicle and the severity of the detected damage is based on predetermined damage sub-classes.

25. The method of claim 23, further comprising the steps of training the neural network to detect damage to the vehicle present in the image and to classify the location of the detected damage and the severity of the detected damage by:
segmenting components of the vehicle, and
detecting at least one segmented component of the vehicle indicative of damage.

26. The method of claim 23, further comprising the steps of training the neural network to detect damage to the vehicle present in the image and to classify the location of the detected damage and the severity of the detected damage by:
segmenting regions of the image based on saliency visualization data, and
detecting at least one segmented region of the image indicative of damage to the vehicle.

27. A non-transitory computer readable medium having instructions stored thereon for vehicle damage detection by a computer vision system which, when executed by a processor, causes the processor to carry out the steps of:
generating a dataset,
training a neural network with a plurality of images of the dataset to learn to detect damage to a vehicle present in an image of the dataset and to classify a location of the detected damage and a severity of the detected damage utilizing segmentation processing, and
detecting the damage to the vehicle and classifying the location of the detected damage and the severity of the detected damage by the trained neural network,
wherein the location of the detected damage is at least one of a front, a rear or a side of the vehicle and the severity of the detected damage is based on predetermined damage sub-classes.

28. The non-transitory computer readable medium of claim 27, the processor further carrying out the step of generating a real dataset based on labeled digital images, each labeled digital image being indicative of an undamaged vehicle or a damaged vehicle.

29. The non-transitory computer readable medium of claim 27, the processor further carrying out the steps of generating a simulated dataset by:
generating components of a simulated vehicle,
linking each component to generate a simulated vehicle,
simulating an external force on the simulated vehicle to generate damage to the simulated vehicle,
identifying and labeling the generated damage to the simulated vehicle, and
storing the damaged simulated vehicle as an image of the simulated dataset.

30. The non-transitory computer readable medium of claim 27, wherein the neural network is a convolutional neural network (CNN) or a fully convolutional network (FCN).

31. The non-transitory computer readable medium of claim 27, the processor further carrying out the steps of generating a simulated dataset including a plurality of images of a reconstructed damaged vehicle based on a plurality of digital images of the damaged vehicle by:
selecting digital images indicative of a fewest number of viewpoints from the plurality of digital images of the damaged vehicle,
transforming the digital images by an encoder to generate two-dimensional dense feature maps utilizing a second neural network,
generating a plurality of three-dimensional feature grids based on the two-dimensional dense feature maps utilizing an unprojection model,
generating a three-dimensional fused feature grid by fusing the plurality of three-dimensional feature grids utilizing a recurrent fusion model,
generating a three-dimensional final grid based on prior constraints and determined features utilizing the second neural network, and
displaying the three-dimensional final grid as the reconstructed damaged vehicle.

32. The non-transitory computer readable medium of claim 31, wherein the reconstructed damage vehicle is one of a computer aided design model or a voxel occupancy grid.

33. The non-transitory computer readable medium of claim 31, the processor further carrying out the steps of:
generating one or more depth maps based on the three-dimensional final grid utilizing a projection model, and
displaying the one or more depth maps as the reconstructed damaged vehicle.

34. The non-transitory computer readable medium of claim 31, wherein the second neural network is a convolutional neural network (CNN) or a liquid state machine (LSM).
